(19) United States
(12) Patent Application Publication
(10) Pub. No.: US 2026/0318717 A1
(43) Pub. Date: Oct. 15, 2026

(54) INDUCTIVE PROXIMITY SENSOR

(71) Applicant: Keyence Corporation, Osaka (JP)

(72) Inventors: Akinori NAGATA, Osaka (JP); Yasunori KAWAGUCHI, Osaka (JP)

(73) Assignee: Keyence Corporation, Osaka (JP)

(21) Appl. No.: 19/557,211

(22) Filed: Mar. 5, 2026

(30) Foreign Application Priority Data
Apr. 14, 2025 (JP) 2025-066162

(51) Int. Cl. G01D 5/22; G01D 11/24

(52) U.S. Cl. CPC G01D 5/2208; G01D 11/245; G01D 2205/50

(57) ABSTRACT

To protect a detection surface of an inductive proximity sensor. An inductive proximity sensor includes, for example, a detection coil that generates a detection signal by a magnetic field, a columnar housing that accommodates the detection coil and includes a detection surface as a bottom surface, and a cap-shaped metal member that is attachable to and detachable from the housing and covers the detection surface when the cap-shaped metal member is mounted to the housing. When the housing is attached to an attachment member including through hole, the cap-shaped metal member is mounted to the housing from a side on which the detection surface is located with respect to the attachment member in a state where the housing is disposed inside the through hole.

### CROSS-REFERENCE TO RELATED APPLICATIONS

The present application claims foreign priority based on Japanese Patent Application No. 2025-066162, filed Apr. 14, 2025, the contents of which are incorporated herein by reference.

### BACKGROUND OF THE INVENTION

### 1. Technical Field

The present invention relates to an inductive proximity sensor.

### 2. Description of the Related Art

Conventionally, there is known an inductive proximity sensor that generates a magnetic field and detects approach of a detection body (metal body) by a change in the magnetic field (see, for example, WO02/075763A).

### SUMMARY OF THE INVENTION

Meanwhile, in the inductive proximity sensor, a detection result may change depending on a metal body other than the detection body in the vicinity of a detection surface.

For example, the detection result may be changed by spatter adhering to the detection surface. Furthermore, an inductive proximity sensor is often used for the purpose of detecting a moving detection body. In this case, there is also a possibility that the detection body comes into contact with the detection surface and the detection surface is damaged.

Note that, conventionally, there is also a member used to cover a detection surface of a proximity sensor (see, for example, a case body 30 of JP2018-205096A). However, the object of the member is merely to improve the attachability of the proximity sensor. Therefore, the configuration does not take replacement of the member itself into consideration.

In view of the above problem, a main object of the present invention is to provide an inductive proximity sensor capable of protecting a detection surface.

For example, according to one embodiment of the present invention, an inductive proximity sensor includes:
a detection coil configured to generate a detection signal by a magnetic field;
a columnar housing configured to accommodate the detection coil and including a detection surface as a bottom surface; and
a cap-shaped metal member attachable to and detachable from the housing and configured to cover the detection surface when the cap-shaped metal member is mounted to the housing,
in which when the housing is attached to an attachment member including a through hole, the cap-shaped metal member is mounted to the housing from a side on which the detection surface is located with respect to the attachment member in a state where the housing is disposed inside the through hole.

Note that other features, elements, steps, advantages, and characteristics will be more apparent from the following detailed description and accompanying drawings in relation thereto.

According to the present invention, an inductive proximity sensor capable of protecting a detection surface can be provided.

### BRIEF DESCRIPTION OF THE DRAWINGS

FIG. 1 is a diagram illustrating an overall configuration of a proximity sensor;

FIG. 2 is a diagram illustrating an installation example of the proximity sensor;

FIG. 3 is a diagram illustrating an outer shape of the proximity sensor;

FIG. 4 is a diagram illustrating an XZ cross section of the proximity sensor;

FIG. 5 is a diagram illustrating functional blocks of a sensor unit;

FIG. 6 is a diagram illustrating a YZ cross section (particularly, a periphery of an operation section) of the proximity sensor;

FIG. 7 is a diagram illustrating an XY cross section (particularly, a periphery of the operation section) of the proximity sensor;

FIG. 8 is a diagram illustrating a relationship between a frequency and a skin depth in various metal materials;

FIG. 9 is a diagram illustrating a function and an effect of the magnetic shield;

FIG. 10 is a diagram illustrating a detection principle of an induction type (pulse type);

FIG. 11 is a diagram illustrating a double coil reception waveform;

FIG. 12 is a diagram illustrating an XZ cross section of a cap-shaped nut;

FIG. 13 is a diagram illustrating an outline of teaching in metal-through;

FIG. 14 is a diagram illustrating detection body signals before and after teaching in metal-through;

FIG. 15 is a diagram illustrating a display pattern according to a relative distance between the proximity sensor and a detection body;

FIG. 16 is a diagram illustrating state transition of the proximity sensor;

FIG. 17 is a diagram illustrating a list of display patterns on a display section;

FIG. 18 is a diagram illustrating a time chart of a display pattern on the display section;

FIG. 19 is a diagram illustrating switching of an operation mode according to an installation position of the proximity sensor;

FIG. 20 is a diagram illustrating a first modification of the proximity sensor;

FIG. 21 is a diagram illustrating an outer shape of a proximity sensor according to the first modification; and

FIG. 22 is a diagram illustrating a second modification of the proximity sensor.

### DETAILED DESCRIPTION

### <Proximity Sensor>

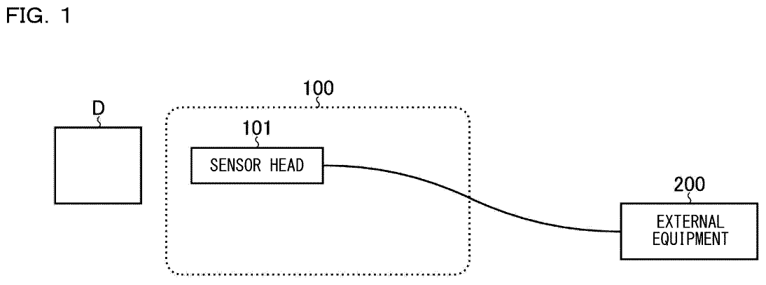

FIG. 1 is a diagram illustrating an overall configuration of a proximity sensor 100. The proximity sensor 100 detects the presence or absence and proximity of a detection body D in a non-contact manner. The proximity sensor 100 may be a pulsed inductive proximity sensor using a pulse waveform excitation current. In this case, the detection body D as a detection target object may be, for example, a metal body. With reference to this drawing, the proximity sensor 100 includes a sensor head 101. Note that, in a case where the component of the proximity sensor 100 is only the sensor head 101, the proximity sensor 100 may be understood as the sensor head 101 itself.

The sensor head 101 generates a magnetic field at a predetermined cycle, and acquires a change in current generated by the magnetic field as a detection signal. The sensor head 101 detects a change in the detection signal according to the presence or absence and proximity of the detection body D, that is, a change in the reception waveform. The sensor head 101 outputs a binary (ON/OFF) detection result to external equipment 200. The external equipment 200 may be, for example, a programmable logic controller (PLC). The sensor head 101 and the external equipment 200 may be physically separable by attaching and detaching a connector or the like.

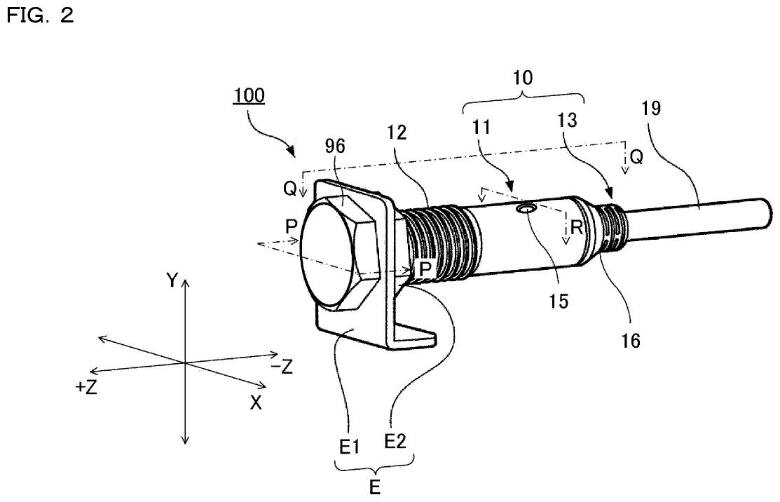

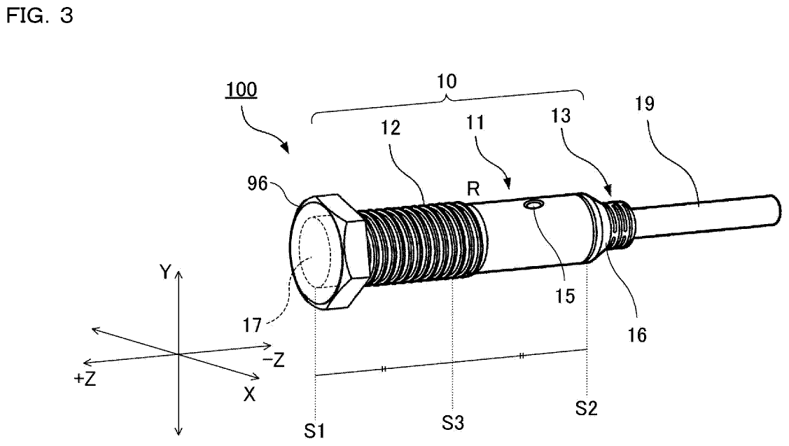

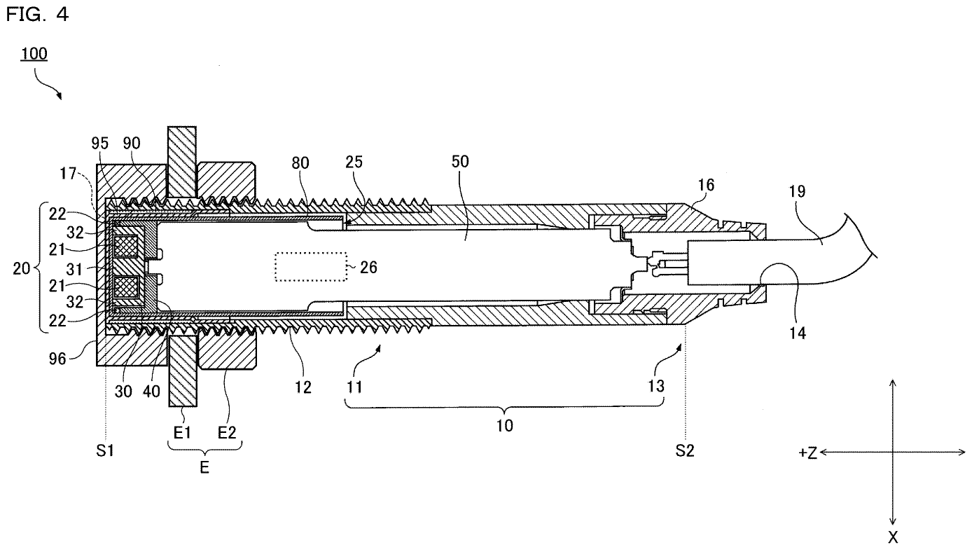

Next, a specific configuration of the proximity sensor 100 will be described with reference to FIGS. 2 to 4. FIG. 2 is a diagram illustrating an installation example of the proximity sensor 100. FIG. 3 is a diagram illustrating an outer shape of the proximity sensor 100, in other words, an outer shape of the sensor head 101. FIG. 4 is an XZ cross-sectional view of the proximity sensor 100. FIG. 4 may be understood as a P-P cross-sectional view of FIG. 2.

The proximity sensor 100 includes, as main components, a case 10, a coil 20, a ferrite core 30, a core holder 40, a substrate 50, an electric shield 80, a magnetic shield 90, a resin cap 95, and a cap-shaped nut 96. Hereinafter, the coil 20, the ferrite core 30, the core holder 40, and the substrate 50 may be collectively referred to as a sensor unit 25.

Note that, as schematically illustrated by a broken-line block in FIG. 4, a detection section 26 that detects the detection body D on the basis of a detection signal generated in the coil 20 may be installed on the substrate 50. The detection signal may be a temporal change in voltage or current generated in the coil 20. The detection section 26 may include, for example, a reception circuit 60 and a control circuit 76 described later.

The case 10 can be understood as a housing that accommodates the coil 20. The case 10 includes a case body portion 11 in which an outer screw 12 is formed. The case body portion 11 can be understood as a cylindrical member in which a second end S2 is opened in a normal direction of a detection surface 17, that is, in a Z-axis direction in the drawing. Hereinafter, a first end S1 may be referred to as a distal end, and the second end S2 may be referred to as a proximal end. Furthermore, in a direction along the Z-axis direction, a direction from the second end S2 to the first end S1 may be referred to as a +Z direction, and a direction from the first end S1 to the second end S2 may be referred to as a −Z direction. The case body portion 11 completely covers the magnetic shield 90, the electric shield 80, and the sensor unit 25 in a circumferential direction thereof. As illustrated in the drawing, the outer screw 12 may be formed on a part of an outer periphery of the case body portion 11. Alternatively, the outer screw 12 may be formed on the entire circumference of the case body portion 11 from the first end S1 to the second end S2. Note that the case body portion 11 may be formed of a cylindrical member in which the first end S1 and the second end S2 are opened.

The resin cap 95 is inserted into and fitted to the first end S1 of the case body portion 11. A bottom surface of the resin cap 95 may be understood as the detection surface 17 of the proximity sensor 100. That is, the detection surface 17 has an outer surface facing the detection body D via the cap-shaped nut 96 and an inner surface facing the coil 20. As described above, the case 10 corresponding to the housing of the proximity sensor 100 can be understood as a columnar member including the detection surface 17 located between the detection body D detected by the detection section 26 and the coil 20 as a bottom surface. On the other hand, a case proximal end portion 13 is inserted and fitted into the second end S2 of the case body portion 11. In the present embodiment, since the case body portion 11 is configured of metal and the detection surface 17 is configured of resin, the resin cap 75 including the detection surface 17 is configured as a member different from the case body portion 11. Note that, since the member constituting the detection surface is configured of the member different from the case body portion 11, there is an advantage regarding machining of the case 10. In this case, a cap member configured of metal may be inserted and fitted into the case body portion 11 instead of the resin cap 95. As an example of the advantage, since the first end S1 of the case body portion 11 can be relatively easily thinned, a space for disposing the coil 20 can be increased. Furthermore, since the cap member itself can be machined with high accuracy at a relatively low cost, variations in the coil arrangement position due to variations in machining and the influence of a detection surface thickness on a coil detection result can be reduced.

The case 10 is provided with an operation section 15. The operation section 15 receives a user's operation for adjusting a detection method by the detection section 26. For example, the operation section 15 functions as an acceptance unit that accepts selection of any one of a plurality of modes having different detectable distances of the detection body D as an operation mode of the detection section 26. Furthermore, the operation section 15 may receive a teaching operation of the user. The teaching operation will be described in detail later.

Furthermore, the case 10 is provided with a display section 16. The display section 16 displays the current setting state indicating the detection method changed according to the operation received by the operation section 15. For example, the display section 16 functions as a notification section that notifies the user of the operation mode of the detection section 26. The display section 16 can be mounted, for example, by turning on and off a part or the whole of the case proximal end portion 13 with an arbitrary emission color. In this case, the display section 16 may include a light emitting element such as a light emitting diode (LED).

Note that the operation section 15 and the display section 16 may be provided on the side opposite to the detection surface 17 with respect to the outer screw 12, that is, on the proximal end side in the normal direction of the detection surface 17, that is, in the Z-axis direction in the drawing. Focusing on the arrangement order, the components may be arranged in the order of the detection surface 17, the outer screw 12, the operation section 15, and the display section 16 from the distal end side toward the proximal end side of the case 10.

Viewed from another perspective, the detection surface 17 is provided at the first end S1 of the case 10. On the other hand, the display section 16 is provided at the second end S2 of the case 10. Furthermore, the operation section 15 is provided at a position closer to the second end S2 than the midpoint S3 between the first end S1 and the second end S2, that is, on the proximal end side.

The proximity sensor 100 further includes a cable 19. One end of the cable 19 is electrically connected to the substrate 50. The cable 19 extends from the substrate 50 to the outside from the inside of the case 10 through the cable attachment port 14 of the case proximal end portion 13. The other end of the cable 19 is disposed outside the case 10 and connected to the external equipment 200.

The coil 20 functions as a detection coil that generates a magnetic field by an excitation current and generates a detection signal by the magnetic field. The coil 20 may be accommodated inside the case body portion 11, particularly in the vicinity of the first end S1. The coil 20 includes a first coil 21 and a second coil 22. The first coil 21 corresponds to a main coil, and the second coil 22 corresponds to a sub-coil. As described above, in the proximity sensor 100, a double coil type having two coils may be adopted as the coil 20 functioning as a detection coil.

The first coil 21 may be wound around a shaft body 31 of the ferrite core 30. The second coil 22 may be wound around an outer peripheral wall 32 of the ferrite core 30. That is, the second coil 22 may be disposed outside the first coil 21 in a radial direction. The second coil 22 may be disposed concentrically with the first coil 21. In the present specification, “disposed concentrically” indicates an arrangement relationship in which the circles are not limited to the same plane. Therefore, in a case where the second coil 22 is disposed concentrically with respect to the first coil 21, the second coil may be disposed on the side (or the opposite side) where the detection body D is detected with respect to the first coil 21.

Note that the length of the second coil 22 in the Z-axis direction may be short. Although details will be described later, when the detectable distance of the proximity sensor 100 is extended, detection accuracy of the proximity sensor 100 may decrease due to a signal component of a magnetic flux line passing through both the detection body D and the attachment member E among magnetic flux lines of a magnetic field generated by the coil 20. In the double coil proximity sensor 100, the detection accuracy can be improved by correcting the detection signal in which the signal component of the magnetic flux line passing only through the detection body D is dominant between the detection body D and the attachment member E, that is, the detection signal in the first coil 21 on the basis of the signal component of the magnetic flux line passing through both the detection body D and the attachment member E. For this purpose, a detection signal in the other coil, that is, the second coil 22 needs to include a signal component of a magnetic flux line passing through both the detection body D and the attachment member E. With the present configuration in which the length of the second coil 22 in the Z-axis direction is short, the magnetic flux line passing through both the detection body D and the attachment member E easily bypasses the −Z direction side of the second coil 22. In other words, a signal component due to the magnetic flux line passing through both the detection body D and the attachment member E is easily included in the detection signal in the second coil 22. Therefore, it is possible to extend the detectable distance of the proximity sensor 100 while maintaining the detection accuracy of the proximity sensor 100.

Furthermore, the second coil 22 may be disposed on the side where the detection body D is detected, that is, on the distal end side with respect to the first coil 21. According to this configuration, the number of magnetic flux lines passing through both the detection body D and the attachment member E, which do not affect the detection signal in the second coil 22 and affect the detection signal in the first coil 21, is reduced, so that the detectable distance can be sufficiently extended while suppressing the influence of the attachment member E.

The ferrite core 30 guides the magnetic field generated from the coil 20. The core holder 40 holds the ferrite core 30 and the substrate 50. Furthermore, the core holder 40 also functions as a support member of the second coil 22. The substrate 50 is electrically connected to the coil 20.

The electric shield 80 is a bottomed cylindrical metal body that inhibits entry of external noise. The electric shield 80 is disposed outside the second coil 22 in the radial direction. The electric shield 80 completely covers the coil 20, the ferrite core 30, and the core holder 40 in the sensor unit 25, and partially covers the substrate 50. A slit may be formed on the bottom surface and the side surface of the electric shield 80 in order to suppress noise of the reception waveform.

The magnetic shield 90 is a ferromagnetic body that guides the magnetic flux lines received by both the first coil 21 and the second coil 22 to avoid the attachment member E that comes out later. The magnetic shield 90 is disposed outside the second coil 22 in the radial direction, more specifically, outside the electric shield 80. The magnetic shield 90 may be wound around the outer periphery of the resin cap 95, for example. The magnetic shield 90 completely covers the coil 20, the ferrite core 30, and the core holder 40 in the sensor unit 25, and partially covers the substrate 50 and the electric shield 80.

The resin cap 95 is inserted into and fitted to the first end S1 of the case body portion 11 to protect a member accommodated in the case 10. Note that, instead of the resin cap 95, a cap made of a material other than resin may be adopted.

The cap-shaped nut 96 is an example of a cap-shaped metal member that can be attached to and detached from the distal end side of the proximity sensor 100, that is, the distal end side of the sensor head 101 by screwing. The cap-shaped nut 96 functions as a metal face for protecting the detection surface 17 from dirt and collision of the detection body D and the like.

Note that, in a case where the cap-shaped nut 96 is contaminated or damaged, the user can easily replace only the cap-shaped nut 96. Consequently, the detection state of the proximity sensor 100 can be stabilized by extremely simple maintenance. However, the cap-shaped metal member is not necessarily in the form of the cap-shaped nut 96 as long as it can protect the detection surface 17 from dirt and collision. That is, the cap-shaped metal member may be coupled to the proximity sensor 100 by a measure other than screwing.

### <Installation Example>

Next, an installation example of the proximity sensor 100 will be described. As illustrated in FIGS. 2 and 4, the proximity sensor 100 is inserted into a through hole penetrating the attachment bracket E1 and fixed by a nut E2 and a cap-shaped nut 96 behind the attachment bracket E1. At this time, the outer screw 12 formed on the outer peripheral surface of the proximity sensor 100 is screwed into the nut E2 and the screw hole (inner screw) of the cap-shaped nut 96. Note that the attachment bracket E1 and the nut E2 can be understood as an attachment member E for fixing the proximity sensor 100.

In this manner, the proximity sensor 100 is fixed by the attachment member E coming into contact with the outer screw 12 provided on the outer periphery of the case 10. That is, the outer screw 12 can be understood as an attached portion with which the attachment member E comes into contact when the proximity sensor 100 is fixed.

A specific attachment procedure is as follows. As a first step, the cap-shaped nut 96 is removed from the proximity sensor 100. As a second step, the proximity sensor 100 is attached to the attachment bracket E1. As a third step, the attachment bracket E1 is sandwiched between the nut E2 attached from the proximal end side of the proximity sensor 100 and the cap-shaped nut 96 attached again from the distal end side of the proximity sensor 100. Through the series of attachment procedures described above, the proximity sensor 100 is fixed to the attachment member E. Note that the proximity sensor 100 may be fixed to the attachment member E by disposing a washer between the nut E2 and the attachment bracket E1 and/or between the cap-shaped nut 96 and the attachment bracket E1. Furthermore, in the present application, the proximity sensor 100 is fixed to the attachment member E such that the attachment bracket E1 is sandwiched between the cap-shaped nut 96 and the nut E2, but a nut different from the cap-shaped nut 96 may be disposed between the cap-shaped nut 96 and the attachment bracket E1, and the proximity sensor 100 may be fixed to the attachment member E such that the attachment bracket E1 is sandwiched between the nut and the nut E2.

Note that the proximity sensor 100 may be tightened until the detection surface 17 abuts the cap-shaped nut 96. At this time, the coil 20 may be located on the distal end side of the attachment bracket E1 in the Z-axis direction. From another point of view, the coil 20 may be located on the distal end side of the opening surface on the proximal end side of the cap-shaped nut 96 in the Z-axis direction. With this configuration, the influence of the attachment member E and the cap-shaped nut 96 can be suppressed.

In the installation example described above, the proximity sensor 100 is surrounded by the attachment member E and the cap-shaped nut 96. In particular, pulsed inductive proximity sensors are often used in this condition. However, the attachment member E and the cap-shaped nut 96 are generally metal bodies. Consequently, the proximity sensor 100 in a state of being surrounded by the attachment member E and the cap-shaped nut 96 may detect not only the detection body D but also the attachment member E and the cap-shaped nut 96 that should not originally be the detection target. Therefore, in order to sufficiently extend the detectable distance of the proximity sensor 100, it is desirable to suppress the influence of the attachment member E and the cap-shaped nut 96.

Note that a user, for example, an installer of the proximity sensor 100 can appropriately change the attached position where the attachment member E and the outer screw 12 are in contact with each other by using the cap-shaped nut 96 having different dimensions in the Z-axis direction. The user can arbitrarily adjust the relative positional relationship between the detection surface 17 and the detection body D by appropriately changing the attached position where the attachment member E and the outer screw 12 are in contact with each other. In particular, in such attachment work, mode switching by the operation section 15 and mode notification by the display section 16 are effective. According to both functions, efficiency can be improved without impairing the degree of freedom of the attachment work. This point will be described in detail later.

In particular, in view of the operability of the user, it is desirable that the operation section 15 and the display section 16 be provided at a position closer to the second end S2 than the attached position. According to this configuration, even if the attached position of the proximity sensor 100 with respect to the attachment member E fluctuates, the user can perform both the operation of the operation section 15 and the confirmation of the display section 16 on the same side with respect to the attachment member E, specifically, on the proximal end side of the attachment member E. Consequently, the labor of the attachment work can be greatly reduced.

### <Sensor Unit>

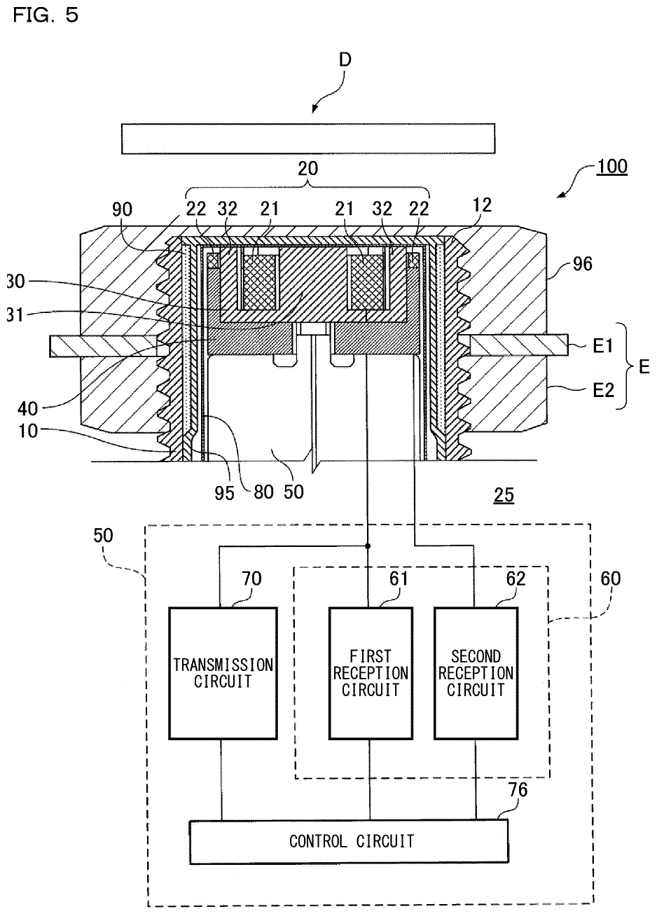

FIG. 5 is a diagram illustrating functional blocks of the sensor unit 25. The sensor unit 25 includes a reception circuit 60, a transmission circuit 70, and a control circuit 76 as main circuit configurations.

The transmission circuit 70 periodically causes a pulsed excitation current to flow through the coil 20 on the basis of a signal from the control circuit 76. The coil 20 generates a magnetic field by periodically flowing the pulsed excitation current.

In a case where the detection body D is within a detection range of the proximity sensor 100, an eddy current is generated in the detection body D by the magnetic field generated from the coil 20. A magnetic field is generated from the detection body D by the eddy current of the detection body D. Here, since the excitation current flowing through the coil 20 is pulsed, the magnetic field generated from the coil 20 is rapidly weakened. Consequently, the eddy current of the detection body D also weakens, and accordingly, the magnetic field generated from the detection body D also weakens. In order to prevent the weakening of the magnetic field generated from the detection body D, a voltage and a current are generated in the coil 20.

The reception circuit 60 detects a voltage or a current generated in each of the first coil 21 and the second coil 22. Since the first coil 21 and the second coil 22 have different arrangements, characteristics of generated voltage or current are also different. By detecting voltages or currents having different characteristics, calculation for suppressing the influence of the attachment member E and the cap-shaped nut 96 becomes efficient. Note that the reception circuit 60 may be configured to detect a voltage or a current generated in at least one of the first coil 21 and the second coil 22.

The control circuit 76 detects the detection body D on the basis of a change in the voltage or current detected by the reception circuit 60. Preferably, the control circuit 76 detects the detection body D on the basis of a change in voltage or current generated in each of the first coil 21 and the second coil 22. Therefore, the proximity sensor 100 can sufficiently extend the detectable distance while suppressing the influence of the attachment member E and the cap-shaped nut 96. Furthermore, the control circuit 76 externally outputs the detection result via the cable 19 described above.

The first coil 21 generates a magnetic field by periodically flowing a pulsed excitation current from the transmission circuit 70. In the present embodiment, the coil 20 that generates the magnetic field by the excitation current is only the first coil 21.

As described above, the first coil 21 may be a main coil that generates a magnetic field during a supply period of the excitation current and generates the first reception waveform M by the magnetic field, that is, the first detection signal during a supply stop period of the excitation current. On the other hand, the second coil 22 may be a sub-coil that does not generate a magnetic field by itself and generates the second reception waveform S by the magnetic field, that is, the second detection signal during the supply stop period of the excitation current.

In a case where an excitation current is applied to only one of the first coil 21 and the second coil 22 to generate a magnetic field, it is preferable to cause an excitation current to flow through only the first coil 21 to generate a magnetic field. As described above, the first detection signal generated by the first coil 21 is different from the second detection signal generated by the second coil 22. In order to extend the detectable distance, it is preferable that at least one detection signal is easily affected by the detection body D. In a case where the magnetic field generated from the coil 20 is directed to a range where the detection body D can be located, that is, a detection range, the detection signal generated by the coil 20 is easily affected by the detection body D. As the coil 20 through which the excitation current flows, a coil wound close to the shaft body 31 of the ferrite core 30 is more likely to direct the generated magnetic field to the detection range. Therefore, it is preferable to generate a magnetic field by causing an excitation current to flow through the first coil 21.

However, the coil 20 that generates the magnetic field by the excitation current may be only the second coil 22, or may be both the first coil 21 and the second coil 22. In a case where an excitation current is caused to flow through both the first coil 21 and the second coil 22 to generate a magnetic field, for example, by directing the direction of the magnetic field of the first coil 21 to the detection body D and directing the direction of the magnetic field of the second coil 22 to the attachment member E, it is possible to obtain a detection result in which the magnetic field of the first coil 21 and the magnetic field of the second coil 22 interfere with each other and the influence of the attachment member E is reduced. In this case, the transmission circuit 70 may include a first transmission circuit that periodically causes a pulsed excitation current to flow through the first coil 21 and a second transmission circuit that periodically causes a pulsed excitation current to flow through the second coil 22.

The transmission circuit 70, the reception circuit 60, and the control circuit 76 may be provided on the substrate 50, for example. With this configuration, the circuit configuration of the sensor unit 25 is stable because the circuit is hardly affected by noise. However, the transmission circuit 70, the reception circuit 60, and the control circuit 76 are not limited to being provided on the substrate 50. For example, the transmission circuit 70, the reception circuit 60, and the control circuit 76 may be provided in different members. Furthermore, any one or two of the transmission circuit 70, the reception circuit 60, and the control circuit 76 may be provided on the substrate 50, and the other circuit(s) may be provided on another substrate or member. Note that the other substrate or member may be disposed inside or outside the case 10.

The reception circuit 60 includes a first reception circuit 61 and a second reception circuit 62. The first reception circuit 61 detects a voltage or a current generated in the first coil 21. The second reception circuit 62 detects a voltage or a current generated in the second coil 22. Hereinafter, the temporal change of the voltage or current detected by the reception circuit 60 may be referred to as a reception waveform or a detection signal. Furthermore, the temporal change of the voltage or current detected by the first reception circuit 61 and the second reception circuit 62 may be referred to as a first reception waveform and a second reception waveform, or a first detection signal and a second detection signal, respectively.

Since the reception circuit 60 includes the first reception circuit 61 and the second reception circuit 62, it is not necessary to switch the reception circuit 60 between the case of detecting the voltage or the current generated in the first coil 21 and the case of detecting the voltage or the current generated in the second coil 22. That is, since the reception circuit 60 includes the first reception circuit 61 and the second reception circuit 62, it is possible to simultaneously detect a voltage or a current generated in the first coil 21 and a voltage or a current generated in the second coil 22. Accordingly, the detection body D can be detected using the voltage or the current generated in the first coil 21 and the voltage or the current generated in the second coil 22 at the same time. Consequently, the proximity sensor 100 can sufficiently extend the detectable distance by improving the detection accuracy.

### <Operation Section>

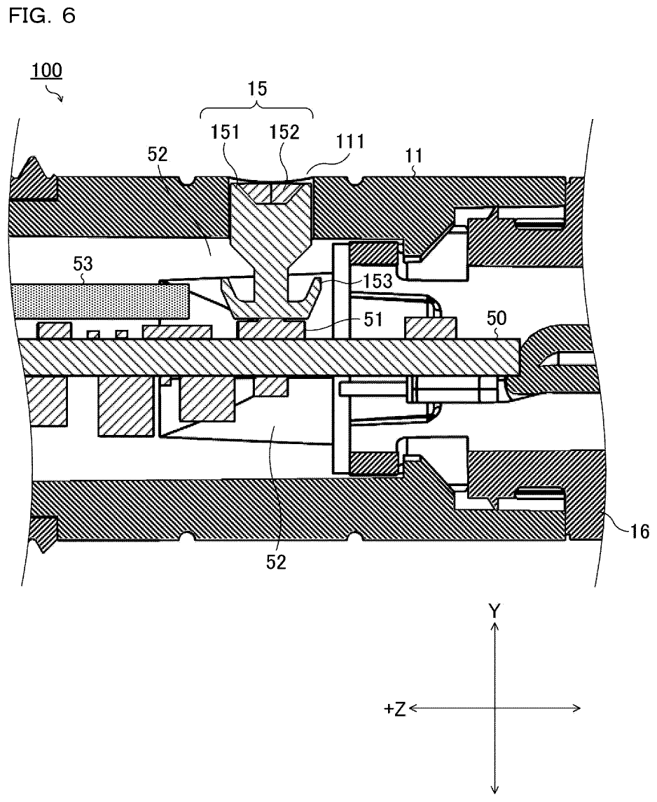

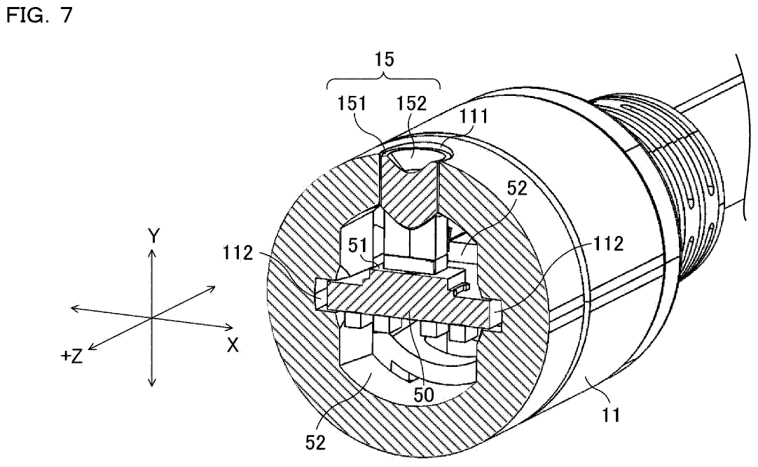

Next, a peripheral structure of the operation section 15 will be exemplified with reference to FIGS. 6 and 7. FIG. 6 is a diagram illustrating a YZ cross section of the proximity sensor 100, particularly, a periphery of the operation section 15. FIG. 6 may be understood as a Q-Q cross-sectional view of FIG. 2. FIG. 7 is a diagram illustrating an XY cross section of the proximity sensor 100, particularly, a periphery of the operation section 15. FIG. 7 may be understood as an R-R cross-sectional view of FIG. 2.

The operation section 15 includes a key member 151 having a button structure that receives a user's pressing operation. A through hole 111 penetrating the outer peripheral surface of the case body portion 11 in the normal direction of the substrate 50, for example, a Y-axis direction is formed. The key member 151 is inserted into the through hole 111. The key member 151 may be disposed such that a lower end portion thereof is in contact with a switch 51 mounted on the substrate 50, and such that an upper end portion thereof is exposed to the outside at a position recessed from the outermost periphery of the case body portion 11.

According to this arrangement, it is difficult for the user to push the operation section 15 with his or her finger. Therefore, an erroneous operation not intended by the user is less likely to occur. In particular, the case body portion 11 is a member with which the user often touches the hand during the attachment work of the proximity sensor 100. In a case where the operation section 15 is provided in such a member, it can be said that this arrangement is effective from the viewpoint of preventing erroneous operation of the operation section 15 in advance.

A key top 152 exposed to the outside via the through hole 111 is formed at the upper end portion of the key member 151. A tool with a sharp tip, for example, a driver or a ballpoint pen, is brought into contact with the key top 152 at the time of a pressing operation by the user. Therefore, the key top 152 may be formed in a shape in which a tool does not easily slip, for example, in a mortar shape. With this configuration, the pressing operation by the tool can be facilitated.

A burr structure 153 having a hook needle shape is formed at a lower end portion of the key member 151. With this configuration, the key member 151 is less likely to fall off from the case body portion 11 before and after filling with a filler 52.

The case body portion 11 is filled with the filler 52 inside. The filler 52 may be a liquid or gel adhesive. The filler 52 may be filled from the opening on the proximal end side of the case body portion 11 in a state where the components except for the case proximal end portion 13 are assembled to the case body portion 11. The filler 52 is basically filled for waterproof purposes.

However, the proximity sensor 100 may collide with the detection body D. In view of this, the mechanical strength against the collision of the detection body D may be increased for the distal end side of the proximity sensor 100, for example, a portion where the outer screw 12 is formed on the outer periphery in the internal space of the case body portion 11. Therefore, the hardness of the filler 52 filled in the portion may be relatively high.

On the other hand, there is no possibility that the proximal end side of the proximity sensor 100 collides with the detection body D. Furthermore, on the proximal end side of the proximity sensor 100, the periphery of the key member 151 is also filled with the filler 52. In view of this, it is important that the pressing operation of the key member 151 is not hindered for the proximal end side of the proximity sensor 100, for example, a portion where the outer screw 12 is not formed on the outer periphery in the internal space of the case body portion 11. Therefore, the hardness of the filler 52 filled in the portion may be relatively low.

As described above, the filler 52 with which the inside of the case body portion 11 is filled is not necessarily limited to one type. For example, various characteristics such as hardness, a thermal expansion coefficient or a color of the filler 52, or a mode related to filling may be arbitrarily adjusted for each filling portion inside the case body portion 11.

Furthermore, a cushioning material 53 may be provided inside the case body portion 11 prior to filling with the filler 52. The cushioning material 53 may be a shrinkable sponge or the like. The cushioning material 53 is desirably disposed near the key member 151. With this configuration, even if the filler 52 thermally expands, the expansion can be offset by the contraction of the cushioning material 53. Therefore, the key member 151 hardly protrudes to the outside from the through hole 111. Note that the burr structure 153 described above can also contribute to preventing the key member 151 from flying out due to thermal expansion of the filler 52.

Furthermore, a pair of substrate fixing grooves 112 extending in the Z-axis direction may be formed on the inner surface of the case body portion 11. The substrate fixing groove 112 supports the substrate 50 so as to sandwich the substrate from both sides in an X-axis direction. As described above, both the through hole 111 into which the key member 151 is inserted and the substrate fixing groove 112 that supports the substrate 50 may be integrally formed in the case body portion 11.

According to this configuration, the substrate 50 is supported in a state of being positioned in advance so as to be perpendicular to the through hole 111. Therefore, the key member 151 inserted into the through hole 111 and the switch 51 installed on the substrate 50 can be reliably brought into contact with each other. Note that a support portion may be provided in the vicinity of the key member 151 from the viewpoint of preventing the deflection of the substrate 50 at the time of the pressing operation by the user.

As described above, when the operation section 15 is provided in the case body portion 11, the installer who performs the attachment work of the proximity sensor 100 can switch the operation mode of the proximity sensor 100 at hand while adjusting the positions of the attachment member E and the proximity sensor 100, for example. Consequently, the attachment work of the proximity sensor 100 can be made efficient.

Note that the display section 16 may be provided at a position farther from the detection surface 17 than the key top 152, that is, on the proximal end side in the normal direction of the detection surface 17, for example, the Z-axis direction. With this configuration, even when the installer of the proximity sensor 100 operates the operation section 15 from the proximal end side, it is difficult to block the visual recognition of the display section 16 by the installer.

As described above, the operation section 15 may be operated at the time of position adjustment between the attachment member E and the proximity sensor 100, and further, may be operated at the time of fine adjustment accompanying position adjustment between the attachment member E and the sensor head 101. Furthermore, the operation section 15 may be operated at the time of adjustment when the detection surface 17 is installed while being surrounded by the attachment member E. Alternatively, the operation section 15 may be operated at the time of adjustment when the cap-shaped nut 96 is positioned between the detection surface 17 and the detection body D. The cap-shaped nut 96 will be described later.

### <Consideration on Induction Type (Pulse Type)>

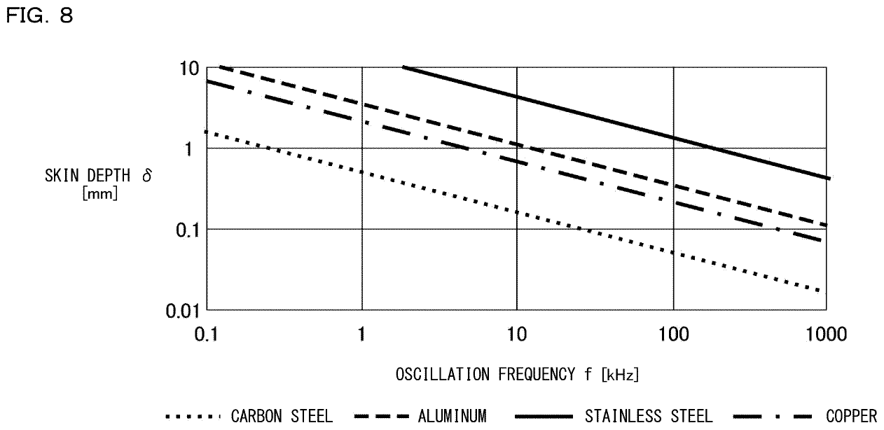

FIG. 8 is a diagram illustrating a relationship between an oscillation frequency f and a skin depth δ in various metal materials. The solid line indicates stainless steel (SUS304), the small broken line indicates carbon steel, the large broken line indicates aluminum (A5052), and the one-dot chain line indicates copper.

In a case where the proximity sensor 100 is a pulsed inductive proximity sensor, the degree of attenuation of the detection magnetic flux line when penetrating the tip metal is determined by the skin depth δ. The skin depth δ is defined by the thickness of the metal at which the magnetic flux line attenuates 1/e (≈1/2.718) times, and is obtained by the following Formula (1).

### [Mathematical Formula 1]

$$δ = \frac{1}{\sqrt{π \cdot f \cdot {μ}_{r} \cdot {μ}_{0} \cdot σ}} \qquad ( 1 )$$

In Formula (1), f represents an oscillation frequency, μr represents relative permeability, μ0 represents vacuum permeability, and σ represents electrical conductivity.

In order to suppress the influence of the metal of the cap-shaped nut 96 on the detection, the metal plate portion 96a covering the detection surface 17 in the cap-shaped nut 96 is desirably designed in a region of the skin depth δ or less. Note that the effective frequency in the pulsed inductive proximity sensor is generally in a low frequency region of 100 kHz to 200 kHz or less. The skin depth δ of carbon steel, aluminum, and copper is shorter than that of stainless steel. Therefore, it can be said that it is difficult to perform design while maintaining mechanical strength. In view of this, the thickness of the tip is desirably designed to be 1.0 mm or less in stainless steel.

Note that, according to the combination of the inductive type (pulse type) and the cap-shaped nut 96, for example, it is possible to achieve both thickening of the cap-shaped nut 96 and extension of the detectable distance. Consequently, the degree of freedom in designing the proximity sensor 100 can be improved.

### <Magnetic Shield>

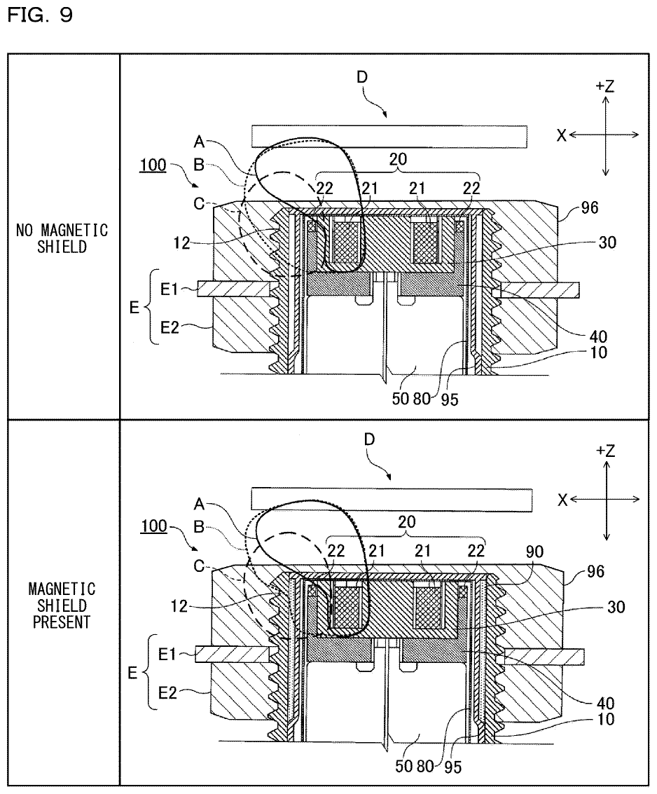

FIG. 9 is a diagram illustrating the function and the effect of the magnetic shield 90. The upper stage and the lower stage respectively illustrate an XZ cross-sectional view of the proximity sensor 100, and in particular, the periphery of the coil 20. The upper stage corresponds to a state in which the magnetic shield 90 is not provided. The lower stage corresponds to a state in which the magnetic shield 90 is provided.

Furthermore, in order to explain the difference between the first detection signal that is the detection signal of the first coil 21 and the second detection signal that is the detection signal of the second coil 22, FIG. 9 models the magnetic field generated by the flow of the excitation current in the first coil 21 by illustrating a representative magnetic flux line. In the upper stage and the lower stage of FIG. 9, the magnetic flux lines received only by the first coil 21 are indicated by thick lines of sign A, the magnetic flux lines received by both the first coil 21 and the second coil 22 are indicated by dotted lines of sign B, and the magnetic flux lines received only by the second coil 22 are indicated by broken lines of sign C. Note that, in FIG. 9, in order to describe the influence of the detection signal due to the path of the magnetic flux line, the “cap-shaped nut 96” in the description of FIG. 9 is understood to refer to a side portion of the cap-shaped nut 96 that can affect the detection signal.

The magnetic field generated by the first coil 21 is configured to reach farther to the +Z direction side, so that the detectable distance of the proximity sensor 100 can be extended. However, since the magnetic field spreads around the first coil 21, when the range of the magnetic field expands toward the +Z direction side, the range also expands in the X-axis direction. That is, since the path of the magnetic flux lines constituting the magnetic field expands not only on the +Z direction side but also in the X-axis direction, some magnetic flux lines may pass through a metal body different from the detection body D. When the proximity sensor 100 is surrounded by the attachment member E and the cap-shaped nut 96 as in the present installation example, many magnetic flux lines may pass through the attachment member E and the cap-shaped nut 96. Since the detection signal changes depending on the presence or absence of the metal body in the range where the magnetic field spreads, it is difficult to distinguish whether the metal body in the range where the magnetic field spreads, that is, the metal body through which the magnetic flux line passes is the detection body D or the attachment member E or the cap-shaped nut 96. For this reason, there is a possibility that the detection accuracy of the proximity sensor 100 is lowered by the magnetic flux lines passing through the attachment member E and the cap-shaped nut 96. As illustrated in the upper stage of FIG. 9, the magnetic flux line (thick line: sign A) received only by the first coil 21 passes only through the detection body D among the detection body D, and the attachment member E and the cap-shaped nut 96. That is, the magnetic flux line indicated by sign A is affected by the detection body D. In a case where the first detection signal is provisionally based only on the magnetic flux line denoted by sign A, the first detection signal changes based on the detection body D. In other words, the signal component based on the magnetic flux line indicated by sign A changes according to the presence or absence and the position of the detection body D. On the other hand, the magnetic flux line (broken line: sign C) received only by the second coil 22 passes only through the attachment member E and the cap-shaped nut 96 among the detection body D, and the attachment member E and the cap-shaped nut 96. That is, the magnetic flux line denoted by sign C is affected by the attachment member E and the cap-shaped nut 96. In a case where the second detection signal is provisionally based only on the magnetic flux line denoted by sign C, the second detection signal changes on the basis of the attachment member E and the cap-shaped nut 96. Moreover, the magnetic flux line (dotted line: sign B) received by both the first coil 21 and the second coil 22 passes through both the detection body D, and the attachment member E and the cap-shaped nut 96. That is, the magnetic flux line indicated by sign B is affected by the detection body D, and the attachment member E and the cap-shaped nut 96. Therefore, the first detection signal of the first coil 21 that receives the magnetic flux line denoted by sign A and the magnetic flux line denoted by sign B changes on the basis of both the detection body D, and the attachment member E and the cap-shaped nut 96. Furthermore, the second detection signal of the second coil 22 that receives the magnetic flux line denoted by sign C and the magnetic flux line denoted by sign B changes on the basis of both the detection body D, and the attachment member E and the cap-shaped nut 96. Note that, in this drawing, for convenience, both the magnetic flux line denoted by sign B and the magnetic flux line denoted by sign C pass only through the cap-shaped nut 96, but from the viewpoint of reducing the detection accuracy of the proximity sensor 100, the cap-shaped nut 96 and the attachment member E can be regarded as the same.

In the present embodiment, the ratio of the signal component affected by the detection body D is larger in the first detection signal than in the second detection signal. Therefore, the proximity sensor 100 detects the detection body D using the first detection signal. Therefore, the detection accuracy of the proximity sensor 100 can be improved by further reducing the signal components of the first detection signal affected by the attachment member E and the cap-shaped nut 96. Since the signal component affected by the attachment member E and the cap-shaped nut 96 included in the first detection signal is derived from the magnetic flux line denoted by sign B, by adopting a configuration in which the magnetic flux line (dotted line: sign B) received by both the first coil 21 and the second coil 22 hardly passes through the attachment member E and the cap-shaped nut 96, the signal component affected by the attachment member E and the cap-shaped nut 96 included in the first detection signal is relatively reduced, and thus, the detection accuracy of the proximity sensor 100 is improved.

As compared with the upper stage without the magnetic shield, in the lower stage with the magnetic shield, the magnetic flux lines (dotted line: sign B) received by both the first coil 21 and the second coil 22 are paths avoiding the attachment member E and the cap-shaped nut 96. Consequently, in the lower stage compared to the upper stage, the magnetic flux lines passing through the attachment member E and the cap-shaped nut 96 are reduced in the magnetic flux lines (dotted line: sign B) received by both the first coil 21 and the second coil 22. In order to achieve the state illustrated in the lower stage, the magnetic shield 90 and the ferrite core 30 are appropriately provided.

Note that, as illustrated in the lower stage, by appropriately disposing the magnetic shield 90, the magnetic flux lines (dotted line: sign B) received by both the first coil 21 and the second coil 22 have a path that further avoids the attachment member E and the cap-shaped nut 96. This is because the magnetic shield 90 guides the magnetic flux lines with relative permeability of a certain degree or more.

Furthermore, by forming the ferrite core 30 into an appropriate shape, a part (dotted line: sign B) of the magnetic flux lines received by both the first coil 21 and the second coil 22 becomes a path that further avoids the attachment member E and the cap-shaped nut 96. This is because the shape of the ferrite core 30 causes the magnetic flux lines to further face the distal end side (+Z direction side).

Furthermore, as illustrated in the lower stage, the magnetic shield 90 is disposed on the outer side in the radial direction of the second coil 22. With this arrangement, the magnetic flux lines (dotted line: sign B) received by both the first coil 21 and the second coil 22 are guided along the magnetic shield 90, so that the path of the magnetic flux lines becomes such that the magnetic flux lines further avoid the attachment member E and the cap-shaped nut 96. Consequently, the proximity sensor 100 can sufficiently extend the detectable distance by suppressing the influence of the attachment member E and the cap-shaped nut 96 on the first detection signal of the first coil 21.

Note that the magnetic shield 90 is required to be disposed as close as possible to the attachment member E and the cap-shaped nut 96, to have high relative permeability, and to have low cost. Furthermore, the magnetic shield 90 itself must not be detected as a metal body. Therefore, the magnetic shield 90 is required to have a high electric resistance, a small thickness, and not to form a loop through which an eddy current flows in the circumferential direction.

### <Detection Principle>

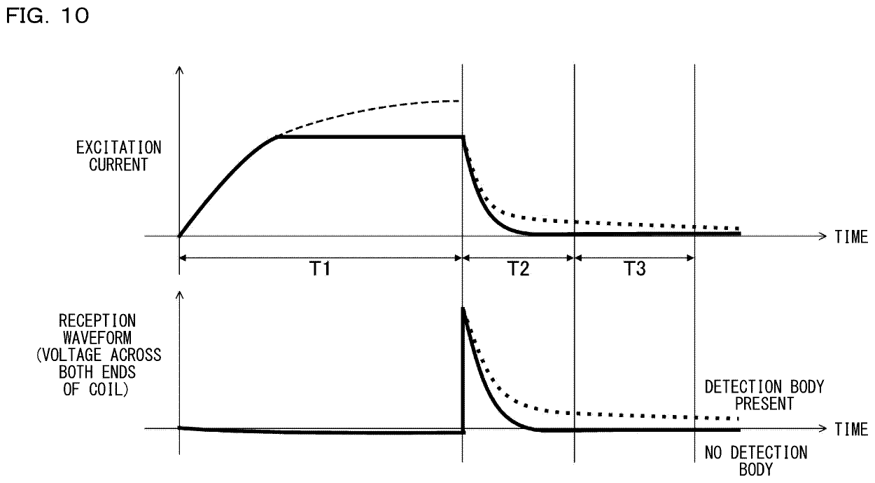

FIG. 10 is a diagram illustrating a detection principle of an induction type (pulse type). A temporal change of the excitation current flowing in the coil 20 is illustrated in the upper stage. In the lower stage, the reception waveform obtained by the coil 20, that is, the temporal change of the voltage across both ends of the coil 20 is illustrated. In the present drawing, for the sake of convenience, description will be given assuming that the coil 20 is a single coil (single coil type).

In a supply period T1 of the excitation current, the excitation current is supplied to the coil 20. Therefore, the coil 20 generates a magnetic field. Note that the excitation current may be subjected to constant current control.

Thereafter, in supply stop periods T2 and T3 of the excitation current, the supply of the excitation current is stopped. Consequently, the magnetic field generated from the coil 20 is weakened. Therefore, a voltage and a current are generated in the coil 20 so as to prevent weakening of the magnetic field.

At this time, the reception waveform obtained by the coil 20 changes according to whether or not the detection body D is within the detection range of the proximity sensor 100. With reference to this drawing, when there is no detection body D, the voltage across both ends of the coil 20 sharply decreases in a relatively short time as indicated by a solid line. On the other hand, when the detection body D is present, as indicated by a small broken line, the voltage across both ends of the coil 20 slowly decreases over a relatively long time. The presence or absence of the detection body D can be determined from such a difference in the reception waveform, for example, a difference in an integral value obtained by integrating the change amount of the reception waveform.

Note that the integration processing of the reception waveform is preferably performed after the decrease in the reception waveform has settled to some extent. In other words, if there is no detection body D, the integration processing of the reception waveform may be started at a timing at which the voltage across both ends of the coil 20 decreases to the minimum value. With reference to this drawing, the integration processing of the reception waveform may be performed on hold until the supply stop period T2 (non-integration period) of the excitation current has elapsed, and then may be performed over the supply stop period T3 (integration period) of the excitation current.

Based on the above detection principle, a double coil type reception waveform using the first coil 21 and the second coil 22 will be described below.

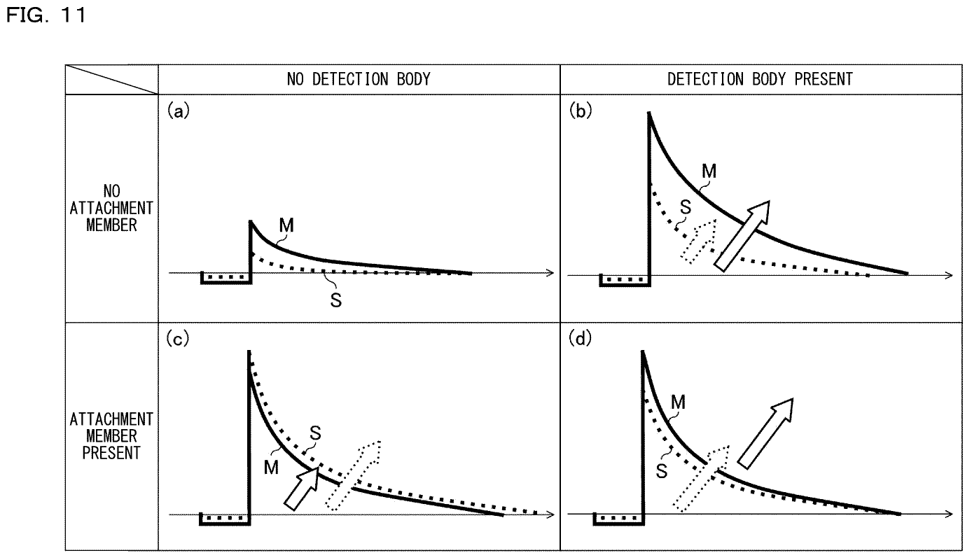

FIG. 11 is a diagram illustrating a reception waveform of a double coil type. In the drawing, the first reception waveform is indicated by sign M, and the second reception waveform is indicated by sign S.

A field (a) illustrates a graph illustrating an image of the reception waveform in a case where the attachment member E and the cap-shaped nut 96 are not provided and the detection body D is not within the detection range. A field (b) illustrates a graph illustrating an image of the reception waveform in a case where the attachment member E and the cap-shaped nut 96 are not provided and the detection body D is within the detection range. A field (c) illustrates a graph illustrating an image of the reception waveform in a case where the attachment member E and the cap-shaped nut 96 are present and the detection body D is not within the detection range. A field (d) illustrates a graph illustrating an image of the reception waveform in a case where the attachment member E and the cap-shaped nut 96 are present and the detection body D is within the detection range. In the graph of each field, the horizontal axis is time, and the vertical axis is the signal intensity of the reception waveform.

Both the field (a) and the field (b) illustrate graphs in a case where the attachment member E and the cap-shaped nut 96 are not provided. As illustrated in the field (a), in a case where the detection body D is not within the detection range, a metal member or the like forming the proximity sensor 100 is slightly detected, so that a first reception waveform M and a second reception waveform S reflecting the detection result appear.

On the other hand, as illustrated in the field (b), in a case where the detection body D is within the detection range, the detection body D is detected, and thus, both the change amount of the first reception waveform M and the change amount of the second reception waveform S are larger than those in the field (a). In particular, since the first reception waveform M obtained by the first coil 21 is more susceptible to the detection body D than the second reception waveform S obtained by the second coil 22, the change amount of the first reception waveform M in the field (b) is larger than the change amount of the second reception waveform S in the field (b).

The field (c) and the field (d) illustrate graphs in a case where the attachment member E and the cap-shaped nut 96 are present. As illustrated in the field (c), even in a case where the detection body D is not within the detection range, the attachment member E and the cap-shaped nut 96 are detected, and thus, both the change amount of the first reception waveform M and the change amount of the second reception waveform S are larger than those in the field (a). In particular, since the second reception waveform S obtained by the second coil 22 is more susceptible to the attachment member E and the cap-shaped nut 96 than the first reception waveform M obtained by the first coil 21, the change amount of the second reception waveform S in the field (c) is larger than the change amount of the first reception waveform M in the field (c).

On the other hand, as illustrated in the field (d), in a case where the attachment member E and the cap-shaped nut 96 are provided and the detection body D is within the detection range, the detection body D is also detected in addition to the attachment member E and the cap-shaped nut 96, and thus, both the change amount of the first reception waveform M and the change amount of the second reception waveform S are larger than those in the field (a). In particular, in a case where the detection body D is within the detection range, the reception waveform obtained by the coil 20 is easily affected by the detection body D. Therefore, the change amount in the field (d) of the first reception waveform M that is more susceptible to the influence of the detection body D than the second reception waveform S is larger than the change amount in the field (d) of the second reception waveform S. That is, as can be seen from the comparison between the field (c) and the field (d), the difference in the change amount of the first reception waveform M caused by the presence or absence of the detection body D is larger than the difference in the change amount of the second reception waveform S caused by the presence or absence of the detection body D.

As illustrated in the field (a) and the field (b), and as illustrated in the field (c) and the field (d), the first reception waveform M is more susceptible to the detection body D than the second reception waveform S. However, focusing only on the first reception waveform M, the difference in the change amount is large between the field (a) and the field (c), and the first reception waveform M is also affected by the attachment member E and the cap-shaped nut 96. In a case where the amount of change in the first reception waveform M in the field (b) and the amount of change in the first reception waveform M in the field (c) are equally large, it is difficult to set a threshold so as to distinguish the first detection signals in these two states, and there is a possibility of erroneous detection. In particular, the longer the distance between the detection body D and the coil 20, the smaller the difference between the amount of change caused by the presence or absence of the detection body D and the amount of change caused by the presence or absence of the attachment member E and the cap-shaped nut 96. Therefore, in a case where the attachment member E and the cap-shaped nut 96 are present, it is difficult to correctly detect the presence or absence of the detection body D, particularly the absence of the detection body D, only from the first reception waveform M.

On the other hand, as illustrated in the field (a) to the field (d), when the first reception waveform M and the second reception waveform S are compared, the first reception waveform M is more susceptible to the detection body D than the second reception waveform S, and the second reception waveform S is more susceptible to the attachment member E and the cap-shaped nut 96 than the first reception waveform M. That is, the second reception waveform S has a different tendency from the first reception waveform M, resulting in a difference in the amount of change. More specifically, in the second reception waveform S, the difference (for example, a difference between the field (a) and the field (b) and a difference between the field (c) and the field (d)) in the change amount of the waveform due to the presence or absence of the detection body D within the detection range is smaller than the first reception waveform M, and the difference (for example, a difference between the field (a) and the field (c), or a difference between the field (b) and the field (d)) in the change amount of the waveform due to the presence or absence of the attachment member E and the cap-shaped nut 96 is larger than the first reception waveform M. Consequently, by calculation based on both the first reception waveform M and the second reception waveform S, the presence or absence of the detection body D can be efficiently detected while the influence of the attachment member E and the cap-shaped nut 96 is suppressed.

For example, the control circuit 76 may calculate a difference value between the first reception waveform M and the second reception waveform S as the detection body signal W (=M-S). According to such calculation processing, the detection body signal W having different values depending on the presence or absence of the detection body D is generated. Consequently, the presence or absence of the detection body D can be correctly detected on the basis of the detection body signal W.

As described above, the proximity sensor 100 can perform detection while suppressing the influence of the surrounding metal including the attachment member E and the cap-shaped nut 96 by adopting the double coil type. Therefore, basically, the detectable distance of the proximity sensor 100 also becomes long. For example, in the proximity sensor 100 adopting the double coil type, the detectable distance can be set longer than 10 mm.

Meanwhile, as the detectable distance of the proximity sensor 100 increases, the demand for fine adjustment of the attachment position of the proximity sensor 100 increases. Therefore, mode switching by the operation section 15 and mode notification by the display section 16 are more useful. This point will be described in detail later.

Furthermore, according to the combination of the double coil type and the cap-shaped nut 96, the first reception waveform M and the second reception waveform S can be arbitrarily subtracted. Consequently, the degree of freedom in designing the proximity sensor 100 can be improved.

### <Teaching (Zero Adjustment)>

As illustrated in the field (a) and field (c) of FIG. 11, even in a case where the detection body D is not in the detection range, the first reception waveform M and the second reception waveform S are basically not 0 values. Consequently, the detection body signal W (=M−S) calculated by the difference calculation between the first reception waveform M and the second reception waveform S may also have some offset value. This is because the proximity sensor 100 erroneously detects a metal body that is not an original detection target, for example, a metal member forming the proximity sensor 100, or the attachment member E and the cap-shaped nut 96 that are in contact with the proximity sensor 100.

Therefore, it is desirable that the detection section 26 that generates the detection body signal W, in particular, the control circuit 76 that is a calculation subject of the detection body signal W, receive a teaching instruction of an installation environment in which the proximity sensor 100 is attached. In the installation environment, the detection section 26 that has received the teaching instruction can perform calibration processing of bringing the detection body signal W obtained in a state where the detection body D is not in the detection range close to a zero value, that is, so-called zero adjustment. Consequently, the influence of the metal body that is not the detection target can be reduced.

Note that the teaching of the proximity sensor 100 may be performed by using, as a trigger, reception of the pressing operation of the user by the operation section 15 described above. In this manner, the teaching operation of the user is preferably received by the operation section 15 provided in the case body portion 11. According to this configuration, the user can also teach the installation environment without any special trouble by simply pushing the operation section 15 while performing the attachment work of the proximity sensor 100. Consequently, the efficiency of the attachment work can be improved. Furthermore, even in a case where the type, for example, the shape or the material of the cap-shaped nut 96 attached to the proximity sensor 100 is different, the above teaching is effective.

### <Cap-Shaped Nut>

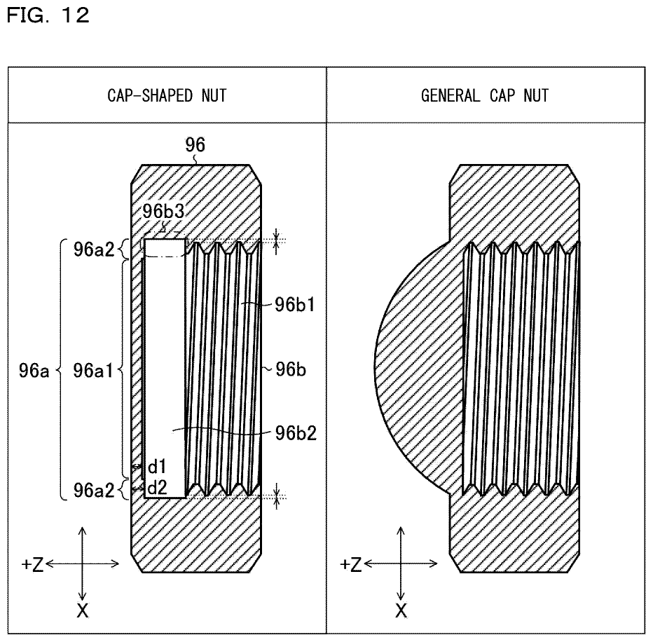

FIG. 12 is a view illustrating an XZ cross section of the cap-shaped nut 96. In the left field, an XZ cross section of the cap-shaped nut 96 is depicted. The left field can be understood as a drawing in which the distal end side of the proximity sensor 100 in FIG. 4 described above is enlarged. Furthermore, in the right field, a general cap nut having a dome-like portion is depicted for comparison. Note that the cap nut having the dome-shaped portion illustrated in this drawing is realized by processing the outer shape into a dome shape, but the inner side of the dome-shaped portion may also be realized by a shape processed along the outer shape.

Note that, for convenience of illustration, the case 10 to which the cap-shaped nut 96 is attached and the attachment member E are not illustrated. For a state in which the cap-shaped nut 96 is attached to the proximity sensor 100, FIGS. 2 to 4 described above may be appropriately referred to.

The cap-shaped nut 96 may be formed of, for example, stainless steel. The cap-shaped nut 96 includes a metal plate portion 96a and a non-through hole 96b. The metal plate portion 96a closes the non-through hole 96b on the distal end side in the Z-axis direction and covers the detection surface 17. That is, the inner surface of the metal plate portion 96a faces the detection surface 17 (not illustrated). On the other hand, the outer surface of the metal plate portion 96a faces the detection body D (not illustrated).

Unlike a general cap nut, in the cap-shaped nut 96, the outer surface of the metal plate portion 96a is formed flat. Therefore, the distance between the detection surface 17 and the +Z-side end portion of the nut mounted on the case 10 in the Z-axis direction can be shortened. When the nut is attached to the case 10 and used, the detectable distance of the proximity sensor 100 is a length obtained by subtracting the distance between the detection surface 17 and the +Z-side end portion of the nut attached to the case 10 from the detectable distance based on the detection surface 17. By shortening the distance between the detection surface 17 and the +Z-side end portion of the nut mounted on the case 10, it is possible to suppress the detectable distance of the proximity sensor 100 from being shortened.

In particular, the metal plate portion 96 includes a thin plate portion 96a1 and a thick plate portion 96a2. The thin plate portion 96a1 may be provided at the center portion of the metal plate portion 96. The thickness d1 of the thin plate portion 96a1 may be, for example, about 0.35 mm to 1.0 mm. The thick plate portion 96a2 may be provided at an outer edge portion of the thin plate portion 96a1, more specifically, at a portion with which the case 10 (not illustrated) abuts. The thickness d3 of the thick plate portion 96a2 may be, for example, about d1+0.1 mm to d1+0.6 mm.

According to this configuration, it is possible to secure the durability of the cap-shaped nut 96 while reducing the thickness of the metal plate portion 96 interposed between the detection surface 17 and the detection body D as much as possible to extend the detectable distance while leaving the thickness at the portion where the case 10 abuts. In particular, in the proximity sensor 100 having a detectable distance of around 10 mm, a slight difference in thickness can be very important.

The non-through hole 96b includes an inner screw 96b1 and a large diameter region 96b2. The non-through hole 96b having this structure can be formed by so-called boring. The inner screw 96b1 is screwed with an outer screw 12 (not illustrated). The inner screw 96b1 may be formed on a part of the non-through hole 96b, specifically, on the proximal end side in the Z-axis direction.

The large diameter region 96b2 may be formed on a part of the non-through hole 96b, specifically, on the distal end side in the Z-axis direction. The inner surface of the large diameter region 96b2 may be a smooth surface that is not threaded. The inner diameter of the large diameter region 96b2 may be designed to be larger than the inner diameter of the thread valley formed in the inner screw 96b1.

That is, in the cap-shaped nut 96, a recess 96b3 is provided on the inner peripheral surface of the non-through hole 96b. When the cap-shaped nut 96 is mounted to the case 10, a gap is generated in the circumferential direction of the case 10 at the distal end portion of the case 10 including the detection surface 17. In other words, the distance between the cap-shaped nut 96 and the second coil 22 increases. Consequently, the change in the second reception waveform obtained by the second coil 22 becomes small.

As described above, in the proximity sensor 100 to which the cap-shaped nut 96 is attached, the metal plate portion 96a is interposed between the detection surface 17 and the detection body D. Therefore, the teaching described above can be particularly useful.

### <Metal-Through>

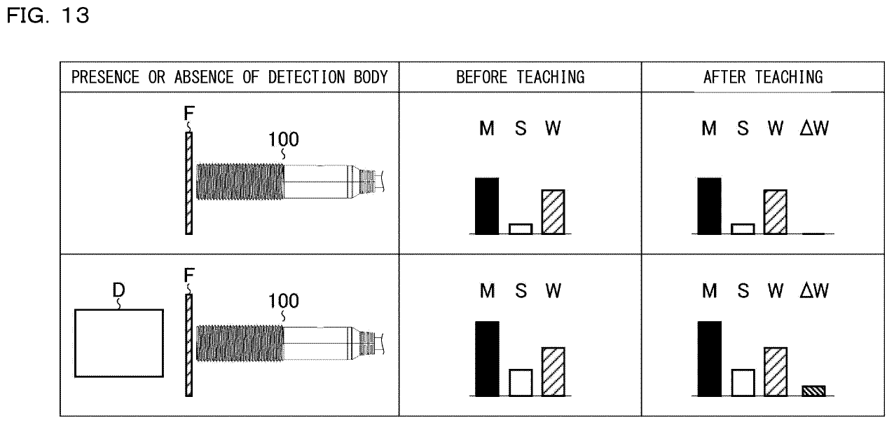

FIG. 13 is a diagram illustrating an outline of teaching in metal-through. The metal-through can be understood as a state in which the metal plate portion F is interposed between the detection surface 17 and the detection body D. Examples of the metal plate portion F include a metal plate portion 96a of the cap-shaped nut 96. Note that the upper stage of the drawing illustrates detection results before and after teaching in a case where there is no detection body D. On the other hand, the lower stage of the drawing illustrates detection results before and after teaching in a case where the detection body D is present. Note that the integral value of the first reception waveform is indicated by sign M, and the integral value of the second reception waveform is indicated by sign S. Furthermore, the detection body signals before and after the teaching are indicated by signs W and ΔW.

As described above with reference to FIG. 8, since the magnetic flux passes through the thin metal plate portion F, for example, the detection body D can be detected by the proximity sensor 100 to which the cap-shaped nut 96 is attached. However, the first reception waveform M and the detection body signal W are affected by the metal plate portion F, that is, the cap-shaped nut 96. In referring to this drawing, the detection body signal W before teaching has a large value as if there is the detection body D even in a case where there is no detection body D. Furthermore, in the state before the teaching, a difference hardly occurs between the change in the integral value of the first reception waveform M due to the presence or absence of the detection body D and the change in the integral value of the second reception waveform S.

Of course, in a case where the detection body D is present, the integrated value of each of the first reception waveform M and the second reception waveform S increases as compared with a case where the detection body D is not present, and there is a difference in the amount of increase, so that the threshold can be set using the difference. However, the threshold of the detection body signal W is often set such that the detection result is ON in a state where there is no metal body F and there is the detection body D. At this time, the integrated values of the first reception waveform M and the second reception waveform S and the detection body signal W have similar values in a state where the detection body D is present without the metal body F and in the upper stage of FIG. 13. For this reason, it is difficult to set a threshold to be compared with the detection body signal W so that the state in the upper stage and the state in the lower stage in FIG. 13 can be distinguished.

Therefore, teaching according to the type of the cap-shaped nut 96, for example, the thickness of the metal plate portion 96a is useful. According to the teaching, the detection body signal W obtained in a state where the detection body D is not in the detection range is adjusted to a zero value. In the drawing, the detection body signal ΔW after the teaching is clearly indicated with respect to the detection body signal W before the teaching. As illustrated in the drawing, the detection body signal ΔW after the teaching is a 0 value in a case where there is no detection body D, and is a signal value (+0) according to the relative distance between the proximity sensor 100 and the detection body D in a case where there is the detection body D.

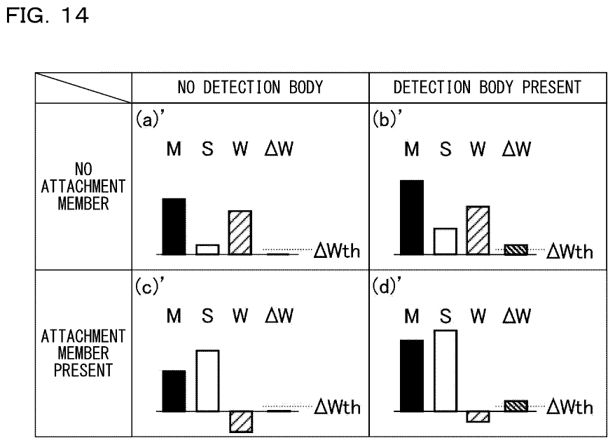

FIG. 14 is a diagram illustrating detection body signals before and after teaching in the metal-through. Note that, in this drawing, the integral value of the first reception waveform is indicated by sign M, and the integral value of the second reception waveform is indicated by sign S. Furthermore, the detection body signals before and after the teaching are indicated by signs W and ΔW.

A field (a)′ illustrates a detection result in a case where the attachment member E is not provided and the detection body D is not within the detection range. In this case, the detection body signal ΔW after the teaching becomes a zero value. On the other hand, a field (b)′ illustrates a detection result in a case where there is no attachment member E and the detection body D is within the detection range. In this case, the detection body signal ΔW after the teaching has a positive signal value (>0) according to the relative distance between the proximity sensor 100 and the detection body D.

Furthermore, a field (c)′ illustrates a detection result in a case where the attachment member E is present and the detection body D is not within the detection range. In this case, since the teaching instruction is received in the state of the field (c)′, the detection body signal ΔW after teaching becomes a zero value. On the other hand, a field (d)′ illustrates a detection result in a case where the attachment member E is present and the detection body D is within the detection range. In this case, the detection body signal ΔW after the teaching has a positive signal value (>0) according to the relative distance between the proximity sensor 100 and the detection body D.

In view of the above behavior, the detection body signal ΔW after teaching may be compared with a positive threshold ΔWth (>0) after predetermined amplification processing is performed. For example, when the detection body signal ΔW is higher than the threshold ΔWth, it can be determined that the detection body D is present. On the other hand, when the detection body signal ΔW is lower than the threshold ΔWth, it can be determined that there is no detection body D. According to such comparison processing, it is possible to correctly detect the presence or absence of the detection body D while reducing the influence of the metal plate portion F that is not the detection target.

That is, the control circuit 76 that performs the above comparison processing can be understood as changing the detection method of the detection body D based on the first reception waveform M and the second reception waveform S according to the positional relationship between the detection surface 17 and the metal plate portion F when the operation section 15 receives the teaching operation. With such a change in the detection method, the control circuit 76 that executes the detection method after the change can detect the detection body D without detecting the metal plate portion F having the above-described positional relationship.

In particular, focusing on the proximity sensor 100 to which the cap-shaped nut 96 is attached, the control circuit 76 may change the detection method of the detection body D based on the first reception waveform M and the second reception waveform S according to the type of the cap-shaped nut 96 when the operation section 15 receives the teaching operation, for example, the thickness of the metal plate portion 96a. With such a change in the detection method, the control circuit 76 that executes the detection method after the change can detect the detection body D without detecting the cap-shaped nut 96.

### <Display Section>

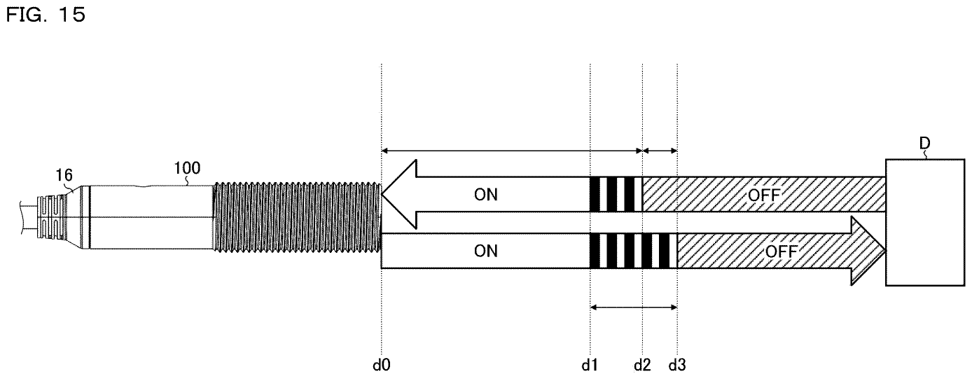

FIG. 15 is a diagram illustrating a display pattern on the display section 16 according to the relative distance d between the proximity sensor 100 and the detection body D.

First, a case where the detection body D moves away from the proximity sensor 100, that is, a case where the relative distance d increases will be described with reference to the right arrow in the lower stage. In this case, when d0≤d<d1, the display section 16 is in an ON state, for example, a lighting state in orange. Note that do may be 0. When d1≤d<d3, a boundary ON state indicating that the display section 16 is ON and in the vicinity of the boundary between ON and OFF, for example, a blinking state in orange is brought about. When d3≤d, the display section 16 is in an OFF state, for example, a lighting state in green.

Next, a case where the detection body D approaches the proximity sensor 100, that is, a case where the relative distance d decreases will be described. In this case, when d2≤d, the display section 16 is turned off. Note that d2<d3 may be satisfied. That is, hysteresis may be imparted to the relative distance d at which the boundary ON state and the OFF state are switched. When d1≤d<d2, the display section 16 is in the boundary ON state. When d0 (=0)≤d<d1, the display section 16 is turned on.

Note that the detectable distance of the proximity sensor 100 may be defined as a relative distance d at which the display section 16 is switched from the OFF state to the boundary ON state, that is, a threshold distance d2, as illustrated in the drawing. However, the definition of the detectable distance is not necessarily limited thereto. For example, the relative distance d at which the display section 16 is switched from the ON state to the boundary ON state, that is, a threshold distance d1 may be defined as the detectable distance. Alternatively, the relative distance d at which the display section 16 is switched from the boundary ON state to the OFF state, that is, a threshold distance d3 may be defined as the detectable distance. Alternatively, the detectable distance of the proximity sensor 100 may be understood as a relative distance d at which the output (ON/OFF) of the proximity sensor 100 is switched. Furthermore, the threshold distances d1, d2, and d3 can be understood as thresholds ΔWth to be compared with the teaching detection body signal ΔW, respectively.

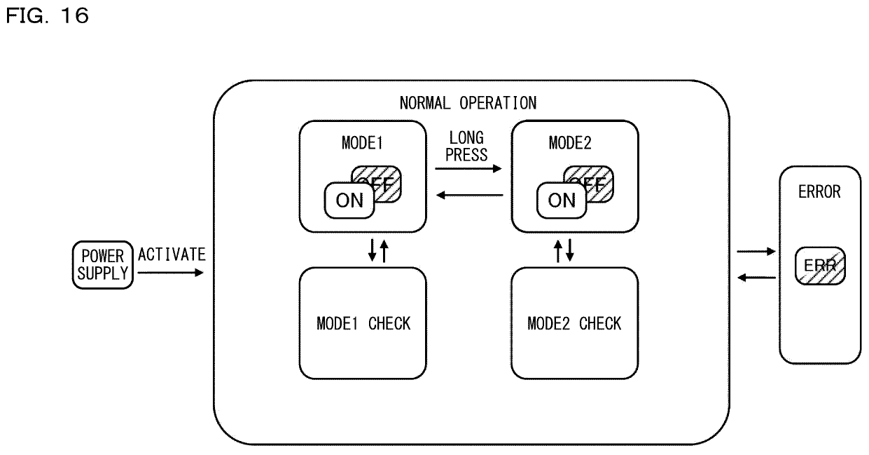

FIG. 16 is a diagram illustrating a state transition of the proximity sensor 100. The proximity sensor 100 is activated by turning on a power supply. When the proximity sensor 100 can operate normally, the operation mode of the detection section 26 is set to either the first mode (MODE1) or the second mode (MODE2). The first mode may be, for example, a long distance mode in which the detectable distance of the proximity sensor 100 is relatively long. The second mode may be, for example, a short range mode or a metal-through mode in which the detectable distance of the proximity sensor 100 is relatively short.

During normal operation of the proximity sensor 100, the display section 16 is lit with a light emission color corresponding to the output (ON/OFF) of the proximity sensor 100. Consequently, the user can visually recognize that the proximity sensor 100 is correctly activated by turning on the power.

The operation section 15 receives a mode switching operation. For example, the first mode and the second mode may be alternately switched every time the operation section 15 is pressed and held for 3 seconds. In this case, a plurality of thresholds ΔWth may be prepared for each operation mode, and may be switched according to the mode switching operation. For example, in the first mode, the threshold ΔWth may be lowered in order to extend the detectable distance. On the other hand, in the second mode, the threshold ΔWth may be raised in order to shorten the detectable distance.

Furthermore, at the time of mode transition, a mode check is executed, and a check result is displayed on the display section 16. For example, when the operation section 15 is pressed and held for 3 seconds in the first mode, the mode transitions to the second mode and the mode check is immediately executed. At this time, the display section 16 blinks twice to notify that the mode is the second mode. On the other hand, when the operation section 15 is pressed and held for 3 seconds in the second mode, the mode transitions to the first mode, and the mode check is immediately executed. At this time, the display section 16 blinks once to notify that the mode is the first mode.

In the mode notification, the emission color of the display section 16 may depend on the output (ON/OFF) of the proximity sensor 100. That is, a configuration in which the output (ON/OFF) of the proximity sensor 100 is indicated by the emission color while indicating the operation mode only by the number of times of blinking may be adopted. With this configuration, the user can switch the operation mode without changing the installation position of the proximity sensor 100, and can confirm whether or not the output (ON/OFF) of the proximity sensor 100 changes. However, as described later, this is not the case in a case where the teaching is automatically executed simultaneously with the mode switching.

Note that the mode notification may be performed only once. Thereafter, the display section 16 may return to the normal display state in each operation mode. Furthermore, the series of mode check and mode notification can also be executed when the operation section 15 is pressed for a short time.

Note that the display section 16 may be turned off when the operation section 15 is pushed to the extent that the operation can be received. Accordingly, when the operation section 15 is pressed for a short time, the display section 16 is turned off, and the display section 16 maintains the turn-off state while the operation section 15 is pressed for a long time. With this configuration, the user can visually recognize that the operation section 15 is pushed in. As described above, the display section 16 may function as a notification section that notifies the user that the key member 151 of the operation section 15 has been pushed in. In particular, in a case where the key member 151 of the operation section 15 is configured to be difficult to push for the purpose of preventing erroneous operation, this configuration can be useful. Note that the notification section may be provided independently of the display section 16.

Moreover, when the mode switching operation is received by the operation section 15, the above-described teaching may be automatically executed simultaneously. That is, the detection section 26 may receive the teaching of the installation environment every time the operation mode is switched. From another point of view, the teaching operation may be triggered by a mode selection operation of selecting any one of a plurality of modes having different detectable distances of the detection body D as the operation mode of the detection section 26.

The mode switching in the operation section 15 is often performed for the purpose of verifying whether the current operation mode is appropriate in a certain installation environment during the attachment work of the proximity sensor 100. With this configuration, it is possible to perform mode switching and teaching necessary to obtain an optimum detection result according to the installation environment of the proximity sensor 100 by a single operation. Consequently, the attachment work of the proximity sensor 100 can be made efficient. Note that, in a case where the configuration is adopted, the mode switching is desirably performed in a state where there is no detection body D within the detection range.

Note that, in a case where any abnormality is detected by the proximity sensor 100, the display section 16 is controlled to be turned on and off in a display pattern corresponding to the content of the error. Furthermore, in a case where the abnormality is eliminated, the display section 16 may return to the normal display state in each operation mode.

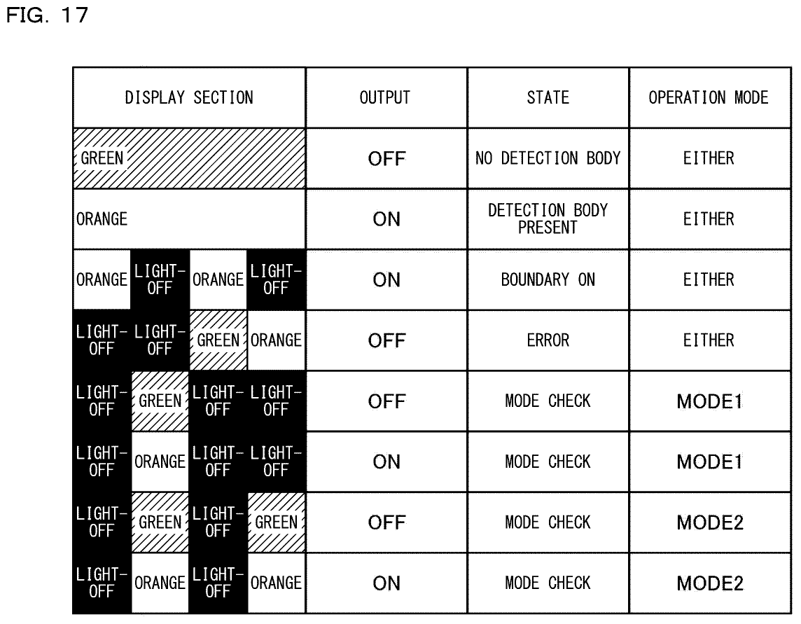

FIG. 17 is a diagram illustrating a list of display patterns on the display section 16. As illustrated in the drawing, the display section 16 functions as a notification section that notifies the user of the detection state of the detection body D, the selection state of the operation mode, and the error occurrence state in display patterns corresponding to the detection state, the selection state of the operation mode, and the error occurrence state.

In a case where there is no detection body D, the display section 16 may be constantly lit in green regardless of the operation mode. At this time, the output of the proximity sensor 100 may be OFF. In a case where the detection body D is present, the display section 16 may be constantly lit in orange regardless of the operation mode. At this time, the output of the proximity sensor 100 may be ON. In the case of the boundary ON state, the display section 16 may blink in orange regardless of the operation mode. At this time, the output of the proximity sensor 100 may be ON.

In a case where an error is detected, the display section 16 may be turned on and off in a display pattern according to the content of the error regardless of the operation mode. The display pattern will be described later.

In a case where the mode check is executed, the display section 16 may be turned on and off in a display pattern according to the output of the proximity sensor 100 and the operation mode. For example, in a case where the output is OFF in the first mode, the display section 16 may blink once in green. In a case where the output is ON in the first mode, the display section 16 may blink once in orange. In a case where the output is OFF in the second mode, the display section 16 may blink twice in green. In a case where the output is ON in the second mode, the display section 16 may blink twice in orange.

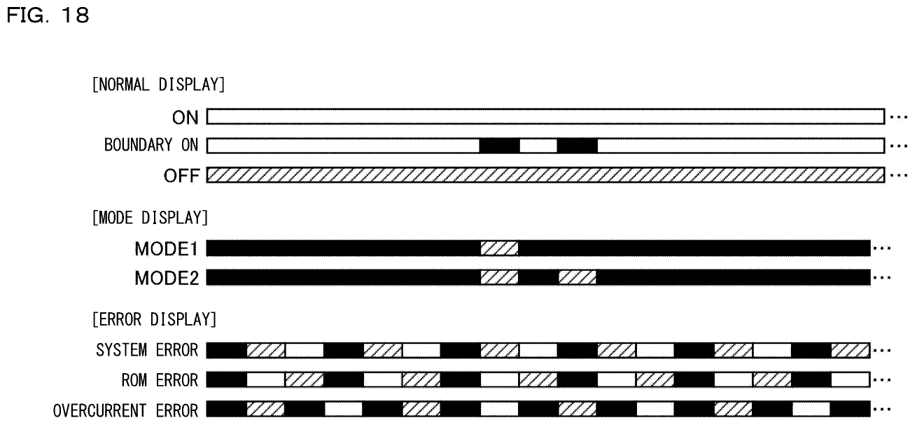

FIG. 18 is a diagram illustrating a time chart of a display pattern on the display section 16. The white region indicates a light-on period in orange. The hatched region indicates a light-on period in green. The black region indicates a light-off period. The minimum light-on period and the minimum light-off period of the display section 16 may be, for example, 0.25 s.

First, the normal display in the upper stage will be described. In the ON state, the display section 16 is constantly lit in orange. In the boundary ON state, the display section 16 blinks in orange. For example, two minimum light-off periods may be included during the light-on period in orange. In the OFF state, the display section 16 is constantly lit in green.

Next, the mode display in the middle stage will be described. In the first mode, the display section 16 blinks once. For example, one minimum light-on period may be included during the light-off period. In the second mode, the display section 16 blinks twice. For example, two minimum light-on periods may be included during the light-off period. Note that the emission color of the display section 16 may depend on the output (ON/OFF) of the proximity sensor 100. In this drawing, the display section 16 blinks in green corresponding to the OFF state.

Finally, the error display in the lower stage will be described. In the case of a system error, the display section 16 is turned on and off in the order of light-off→green→orange→light-off . . . . In the case of a read only memory (ROM) error, the display section 16 is turned on and off in the order of light-off→orange→green→light-off . . . . In the case of an overcurrent error, the display section 16 is turned on and off in the order of light-off→green→light-off→orange→light-off . . . .

However, the above display pattern is merely an example, and it goes without saying that any display pattern can be adopted.

### <Mode Switching and Mode Notification>

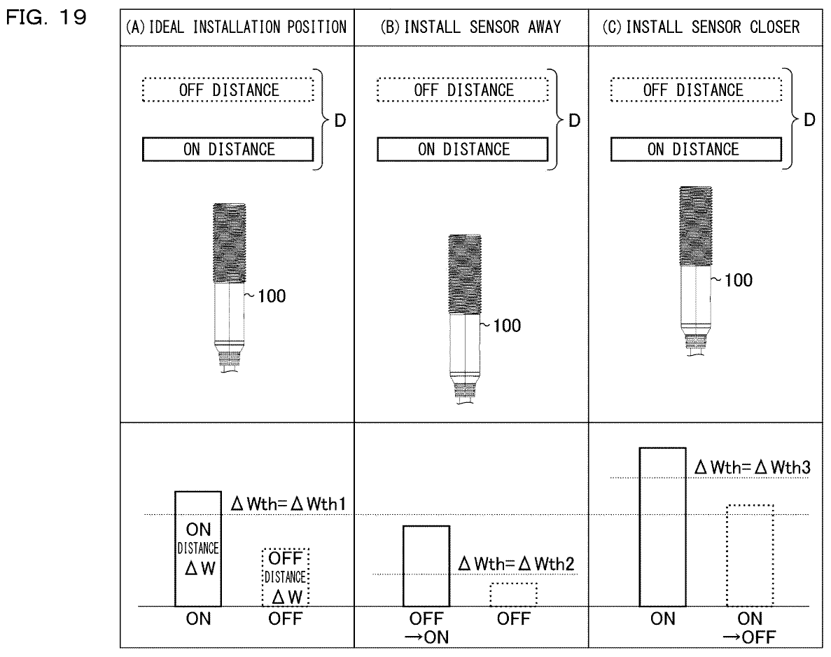

FIG. 19 is a diagram illustrating switching of the operation mode according to the installation position of the proximity sensor 100. Note that, in the upper stage of a column (A), a state in which the proximity sensor 100 is attached to an ideal installation position with respect to the detection body D is depicted. In the upper stage of a column (B), a state in which the proximity sensor 100 is installed away from the detection body D is depicted. In the upper stage of a column (C), a state in which the proximity sensor 100 is installed close to the detection body D is depicted. Furthermore, in the lower stage of each column, a detection body signal ΔW and a threshold ΔWth after teaching are depicted.

In the attachment work of the proximity sensor 100, it is very difficult to attach the proximity sensor 100 to the ideal installation position of the column (A) at once. When the proximity sensor 100 is actually attached, it is often the installation position of the column (B) or the column (C). Therefore, in the conventional attachment work, it may be necessary to perform complicated work of repeatedly finely adjusting the installation position to approach the ideal installation position of the column (A).

On the other hand, as described above, in the case of the proximity sensor 100, mode switching by the operation section 15 and mode notification by the display section 16 are possible. By utilizing these functions, the user does not need to finely adjust the installation position of the proximity sensor 100, but only needs to switch the optimum operation mode according to the installation position of the proximity sensor 100, and in other words, switch the threshold ΔWth. That is, it is not necessary to finely adjust the installation position of the proximity sensor 100.

First, consider a case where the proximity sensor 100 is attached to the installation position of the column (A). In this case, a first threshold ΔWth1 may be set as the threshold ΔWth. According to this setting, the detection body signal ΔW is above the threshold ΔWth in a case where the detection body D is at the ON distance, and the detection body signal ΔW is below the threshold Wth in a case where the detection body D is at the OFF distance. As a result, the presence or absence of the detection body D can be correctly detected.

Next, a case where the proximity sensor 100 is attached to the installation position of the column (B) will be considered. In this case, a second threshold ΔWth2 lower than the first threshold ΔWth1 may be set as the threshold ΔWth. That is, the detectable distance of the proximity sensor 100 is preferably extended. If the first threshold ΔWth1 is set as it is as the threshold ΔWth, even if the detection body D is at the ON distance, the detection body signal ΔW falls below the threshold ΔWth1, so that the output may be erroneously OFF. On the other hand, according to the present setting, in a case where the detection body D is at the ON distance, the detection body signal ΔW exceeds the threshold ΔWth, and in a case where the detection body D is at the OFF distance, the detection body signal ΔW falls below the threshold Wth. As a result, the presence or absence of the detection body D can be correctly detected.

Finally, consider a case where the proximity sensor 100 is attached to the installation position of the column (C). In this case, a third threshold ΔWth3 higher than the first threshold ΔWth1 may be set as the threshold ΔWth. That is, the detectable distance of the proximity sensor 100 is preferably shortened. If the first threshold ΔWth1 is set as it is as the threshold ΔWth, even if the detection body D is at the OFF distance, the detection body signal ΔW exceeds the threshold ΔWth1, so that the output may be erroneously ON. On the other hand, according to the present setting, in a case where the detection body D is at the ON distance, the detection body signal ΔW exceeds the threshold ΔWth, and in a case where the detection body D is at the OFF distance, the detection body signal ΔW falls below the threshold Wth. As a result, the presence or absence of the detection body D can be correctly detected.

As described above, according to the mode switching by the operation section 15, complicated fine adjustment of the installation position becomes unnecessary. Consequently, the attachment work of the proximity sensor 100 can be made efficient.

Furthermore, according to the mode notification on the display section 16, it can be easily determined whether or not the selected operation mode is appropriate. For example, prior to fine adjustment of the installation position, the user can confirm whether or not the detection body D is correctly detected in the current operation mode while sequentially switching a plurality of operation modes prepared in advance. At this time, according to the mode notification on the display section 16, the user can easily grasp whether or not the verification has been completed in all the operation modes. Therefore, attachment work of the proximity sensor 100 can be made efficient.

Furthermore, according to the mode notification on the display section 16, even in a case where it is necessary to adjust the installation position of the proximity sensor 100, the user can know whether to move the proximity sensor 100 away from the detection body D or, conversely, whether to move the proximity sensor 100 close to the detection body D. For example, in a case where the detection body D is not correctly detected even in the operation mode in which the detectable distance of the proximity sensor 100 is the shortest, it is necessary to move the proximity sensor 100 away from the detection body D. Conversely, in a case where the detection body D is not correctly detected even in the operation mode in which the detectable distance of the proximity sensor 100 is the longest, it is necessary to bring the proximity sensor 100 close to the detection body D. With such knowledge, the attachment work of the proximity sensor 100 can be made efficient.

Note that the cap-shaped nut 96 described above may be used in a situation where the possibility of collision between the detection body D and the detection surface 17 is high, that is, in a situation where it is normal that the detection body D exists at a position relatively close to the detection surface 17. Therefore, in a situation where the cap-shaped nut 96 is used, the operation mode of the proximity sensor 100 may be switched to the short distance mode or the metal-through mode. However, the shorter the detectable distance of the proximity sensor 100, the higher the possibility of collision between the detection body D and the detection surface 17. Therefore, the operation mode of the proximity sensor 100, and thus, the detectable distance of the proximity sensor 100 may be appropriately set within a range in which the possibility of collision can be reduced and the detection accuracy can be improved.

### <First Modification>

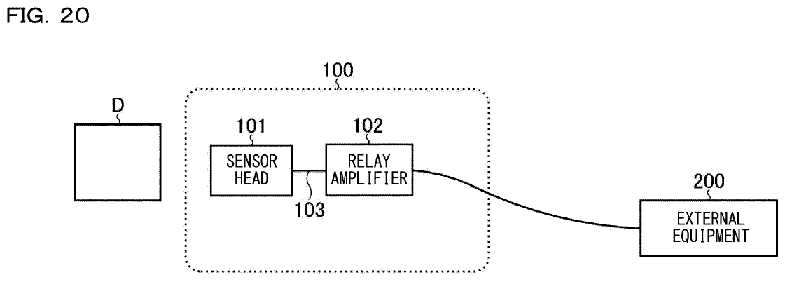

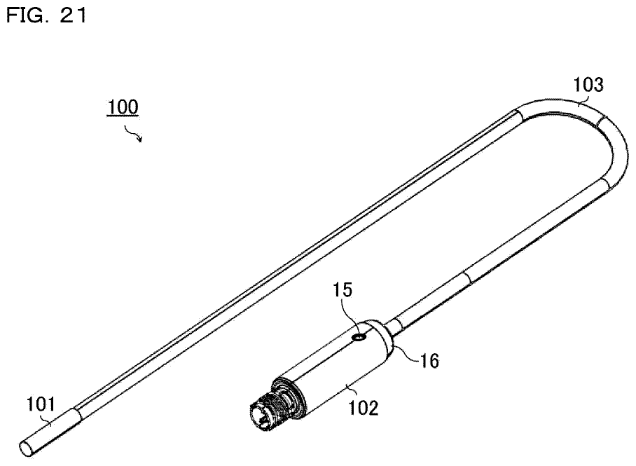

FIG. 20 is a diagram illustrating a first modification of the proximity sensor 100. FIG. 21 is a diagram illustrating an outer shape of the proximity sensor 100 according to the first modification. The proximity sensor 100 of the present modification includes a relay amplifier 102 and a cable 103 in addition to the sensor head 101 described above.

The relay amplifier 102 is a separate body from the sensor head 101, and is connected to the sensor head 101 via the cable 103. The relay amplifier 102 receives a detection signal from the sensor head 101 via the cable 103, for example, the first detection signal and the second detection signal described above. The relay amplifier 102 includes the above-described detection section 26. The relay amplifier 102 outputs a detection result (ON/OFF) obtained by the detection section 26 to the external equipment 200. The relay amplifier 102 and the external equipment 200 may be physically separable by attaching and detaching a connector or the like.

On the other hand, the sensor head 101, the relay amplifier 102, and the cable 103 are provided to the user in a state where they cannot be separated from each other. The distance between the sensor head 101 and the relay amplifier 102 may be, for example, about 30 cm. The relay amplifier 102 can be understood as a component that cannot be completely accommodated in the sensor head 101, for example, the above-described detection section 26 is accommodated as a separate body. Therefore, the configuration of the relay amplifier 102 may be relatively simple. Such a relay amplifier 102 can be understood as an inseparable portion connected to the sensor head 101 and hence to the above-described case body portion 11.

Note that, in the proximity sensor 100 of the present modification, at least one of the operation section 15 and the display section 16 described above may be provided in the relay amplifier 102.

### <Second Modification>

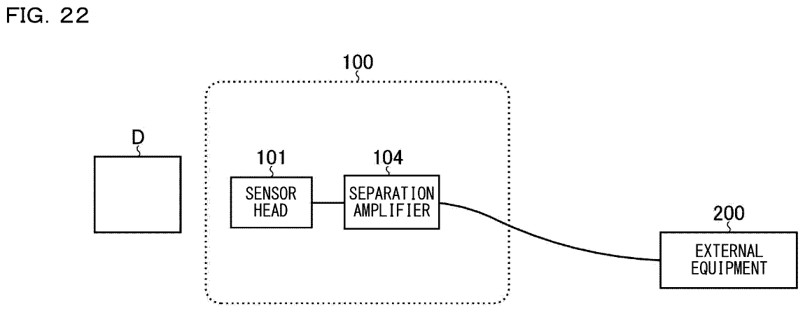

FIG. 22 is a diagram illustrating a second modification of the proximity sensor 100. The present modification can be understood as a comparative example contrasted with the second modification (FIG. 20) described above. With reference to the drawing, the proximity sensor 100 of the present modification includes a separation amplifier 104 instead of the relay amplifier 102.

The separation amplifier 104 is a separate body from the sensor head 101, receives a detection signal from the sensor head 101, and outputs a detection result (ON/OFF) to the external equipment 200. The separation amplifier 104 and the external equipment 200 may be physically separable by attaching and detaching a connector or the like. In these respects, there is no particular difference between the relay amplifier 102 and the separation amplifier 104.

However, unlike the relay amplifier 102, the separation amplifier 104 is provided to the user in a state of being separable from the sensor head 101. That is, the sensor head 101 and the separation amplifier 104 may be physically separable by attaching and detaching a connector or the like. The distance between the sensor head 101 and the separation amplifier 104 may be, for example, about 2 m. The separation amplifier 104 may be understood as adding various additional functions to the proximity sensor 100. Therefore, the configuration of the separation amplifier 104 can be relatively complicated. Such a separation amplifier 104 is not different from the relay amplifier 102 at first glance, but is considered not to correspond to the above-described inseparable portion.

### <Other Modifications>

Note that, in addition to the above embodiments, various modifications can be made to the present invention without departing from the spirit of the technical creation.

For example, in the above embodiment, the outer screw 12 is exemplified as the attached portion of the proximity sensor 100. However, the attached portion of the proximity sensor 100 is not limited thereto, and may be, for example, a setscrew, a set screw, or a split jig.

Furthermore, the operation section 15 may have a trimmer structure that is rotationally operated with a negative screwdriver or the like. Alternatively, the operation section 15 may have a dial structure rotated in the circumferential direction of the case 10. With these configurations, the operation section 15 also serves as the display section 16. That is, a notification measure of the operation mode is not limited to the display section 16, and may mechanically indicate the operation mode by a rotation gauge, a dial, or the like, or may notify the operation mode by sound, buzzer sound, or the like.

As described above, the above embodiment should be considered to be illustrative in all respects and not restrictive. Furthermore, the technical scope of the present invention is defined by the claims, and should be understood to include all modifications falling within the meaning and scope equivalent to the claims.

What is claimed is:

1. An inductive proximity sensor comprising:
a detection coil configured to generate a detection signal by a magnetic field;
a columnar housing configured to accommodate the detection coil and including a detection surface as a bottom surface; and
a cap-shaped metal member attachable to and detachable from the housing and configured to cover the detection surface when the cap-shaped metal member is mounted to the housing,
wherein when the housing is attached to an attachment member including a through hole, the cap-shaped metal member is mounted to the housing from a side on which the detection surface is located with respect to the attachment member in a state where the housing is disposed inside the through hole.

2. The inductive proximity sensor according to claim 1, wherein an outer screw is provided on an outer peripheral surface of the housing, and the cap-shaped metal member includes a cap-shaped nut capable of being screwed into the outer screw.

3. The inductive proximity sensor according to claim 2, wherein a recess is provided on an inner peripheral surface of the cap-shaped nut, and when the cap-shaped nut is mounted to the housing, a gap is generated in a circumferential direction of the housing at a distal end portion of the housing including the detection surface.

4. The inductive proximity sensor according to claim 2, wherein the cap-shaped nut includes a metal plate portion configured to cover the detection surface, and
the metal plate portion includes a thin plate portion provided at a center portion of the metal plate portion, and a thick plate portion provided at an outer edge portion of the thin plate portion.

5. The inductive proximity sensor according to claim 4, wherein a thickness of the thin plate portion is 0.35 mm to 1.0 mm, and a thickness of the thick plate portion is thicker than a thickness of the thin plate portion by 0.1 mm to 0.6 mm.

6. The inductive proximity sensor according to claim 1, wherein the detection coil is located on a distal end side of an opening surface of the cap-shaped metal member in a normal direction of the detection surface.

7. The inductive proximity sensor according to claim 1, further comprising:
a detection section configured to detect a detection body on a basis of the detection signal generated in the detection coil; and
a reception section configured to receive, as an operation mode of the detection section, selection of any one of a plurality of modes having different detectable distances of the detection body.

8. The inductive proximity sensor according to claim 1, further comprising:
a detection section configured to detect a detection body on a basis of the detection signal generated in the detection coil; and
an operation section configured to receive a teaching operation of a user,
wherein the detection section changes a detection method of the detection body on a basis of the detection signal according to a type of the cap-shaped metal member when the operation section receives the teaching operation, and
the detection section that executes the changed detection method does not detect the cap-shaped metal member and detects the detection body.

9. The inductive proximity sensor according to claim 1, further comprising a transmission circuit configured to periodically cause a pulsed excitation current to flow through the detection coil,
wherein the detection coil generates a magnetic field during a supply period of the excitation current and generates the detection signal by the magnetic field during a supply stop period of the excitation current.

10. The inductive proximity sensor according to claim 1, further comprising a detection section configured to detect a detection body on a basis of the detection signal generated in the detection coil,
wherein the detection coil includes: a first coil configured to generate the magnetic field during a supply period of an excitation current and generate a first detection signal by the magnetic field during a supply stop period of the excitation current; and a second coil configured to generate a second detection signal by the magnetic field during the supply stop period of the excitation current, and
the detection section detects the detection body on a basis of the first detection signal and the second detection signal.
